(19) United States
(12) Patent Application Publication
(10) Pub. No.: US 2026/0072488 A1
(43) Pub. Date: Mar. 12, 2026

(54) METHODS AND APPARATUS FOR BATTERY SWAPPING IN UTILITY LOCATOR DEVICES AND OTHER COMPLEX BOOTABLE ELECTRONIC DEVICES

(71) Applicant: SeeScan, Inc., San Diego, CA (US)

(72) Inventor: Mark S. Olsson, La Jolla, CA (US)

(21) Appl. No.: 19/324,880

(22) Filed: Sep. 10, 2025

Related U.S. Application Data
(60) Provisional application No. 63/694,102, filed on Sep. 12, 2024.

(51) Int. Cl. G06F 1/26; G01R 31/387; G06F 9/4401

(52) U.S. Cl. CPC G06F 1/263; G01R 31/387; G06F 9/4401

(57) ABSTRACT

This disclosure relates to an apparatus and methods for swapping out batteries in complex bootable battery powered devices with minimal disruption. Such complex bootable battery powered devices may have various operation settings that a user may not need to reconfigure upon swapping out a battery due to the battery swapping apparatus methods disclosed. Further, such battery-swapping apparatus may avoid boot time by powering the device via internal capacitance or a secondary power source in the device. Likewise, the complex bootable battery powered devices may automatically restart wherein a charged battery is installed prior to the depletion of the internal power capacity of the device. The battery-swapping apparatus, amongst many battery-powered host devices, may be employed in various devices used utility locator devices and other devices used in utility locating systems and pipe inspection systems.

### CROSS-REFERENCE TO RELATED APPLICATIONS

This application claims priority under 35 U.S.C. § 119 (c) to U.S. Provisional Patent Application Ser. No. 63/694,102 entitled METHODS AND APPARATUS FOR BATTERY SWAPPING IN UTILITY LOCATOR DEVICES AND OTHER COMPLEX BOOTABLE ELECTRONIC DEVICES, filed Sep. 12, 2024, the content of which is incorporated by reference herein in its entirety for all purposes.

### FIELD

This disclosure relates generally to methods and apparatus for swapping batteries in complex bootable electronic devices that avoid unnecessary interruptions. More specifically, but not exclusively, the disclosure relates to methods and apparatus for swapping batteries in utility locator devices and other complex bootable electronic devices that avoid unnecessary interruptions and automatically restoring such devices to a fully operational state when a charged battery is installed.

### BACKGROUND

We have become increasingly reliant on a wide variety of battery-powered electronic devices to aid in accomplishing various tasks and to bring convenience into our modern lives. Consequently, a dead or depleted battery may be a source of frustration for a user. In many electronic devices, this frustration may end with the replacement of the dead battery. In other devices, referred to herein as “complex bootable electronic devices,” there are additional frustrations that may arise from a dead or depleted battery. A complex bootable electronic device, as used herein, may refer to any tool, instrument, or other battery-powered device that, upon start up, may initially go through a boot procedure which is a process by which the device hardware is initialized and the operating system and firmware may be loaded to prepare the complex bootable electronic device for use. The boot procedure, which may be a lengthy process, may generally need to be initialized via the user (e.g., via pressing a button or the like). Such devices may generally include a series of “operation setting” which may be settings or selections on the complex bootable electronic device configurable by the user (e.g., screen brightness, audio levels, wireless connections to other devices, and other settings which may be unique to the particular electronic device).

In prior art complex bootable electronic devices, it is common that the current operation setting may be lost when a battery dies or is removed from the electronic device. This may require a user, upon reinstalling a charged battery, to unnecessarily spend time recalling the most recent operation settings of the electronic device and reconfiguring the electronic device to match those operation settings. Such a scenario becomes increasingly burdensome to a user where the electronic device is increasingly complex and may have many different operation settings to reconfigure.

Further, a complex bootable electronic device may have a lengthy boot time once a battery has been replaced. As such, a dead or depleted battery may be an incredible inconvenience and may even negatively impact the outcomes produced by the particular complex bootable electronic device. For instance, a global navigation satellite system (GNSS) receiver may, upon replacing a dead or depleted battery, require several minutes of boot or load time to acquire a fix on the signals from a sufficient number of navigation satellites in order to accurately determine positions. It also requires a user to restart the device via pressing a button or the like adding to the inconvenience of a dead or depleted battery. Having a user wait for a GNSS receiver and/or other complex bootable electronic device to reboot once a dead or depleted battery has been replaced may be incredibly inconvenient. Likewise, the fix of the GNSS receiver may initially be of lesser quality (e.g., due to acquired signal from fewer satellites) than the GNSS receiver prior to dead or depleted battery and as such may produce position solutions of lower quality on initial reboot.

The pain of a depleted battery may be particularly distressing in some complex bootable electronic devices such as with utility locator devices. Utility locator devices are generally hand-carried instruments that may be moved through a locate environment to measure electromagnetic signals in order to determine positions and map one or more utility lines which may be buried in the ground. In known utility locator devices, the reboot procedure may be lengthy process and requires a user to initialize the boot process via the push of a button or the like further adding to the inconvenience of a dead or depleted battery. Known utility locator devices, upon reboot, may have a series of operation settings that may need to be reconfigured by a user (e.g., screen brightness levels, audio levels, connections to other system devices, and the like). Because of the complexity of a user locator device, reconfiguring of operation settings may be timely and burdensome to the user.

Further, it is vital that utility lines prior to excavation are located and mapped as precisely as possible to avoid striking a utility line and causing a disruption to services and avoid potential for electrocutions, floods, and even explosions. To facilitate such precision, a utility locator device may employ one or more GNSS receivers and antennas which may be used in addition to inertial navigation and like sensors to determine geolocations in the world frame. The GNSS receiver(s), as well as other complex elements in the utility locator device that may have a boot process, may cause a tremendous delay upon experiencing a dead or depleted battery when restarting the utility locator device after replacing the battery. As such, a dead or depleted battery may be a tremendous inconvenience to the user. It should also be noted, that because a locate procedure often occurs in or near busy roads and highways, the lengthy reboot time could keep a user in a dangerous situation for longer than necessary. Further, since geolocations may not be initially as accurate as desired upon reboot, the precision of mapping of utility lines may be negatively impacted. For instance, when a battery dies in known utility locator devices, GNSS receivers and radios for receiving GNSS correction data (e.g., signals associated with State Space Representation [SSR], Precise Point Positioning [PPP], Real-Time Kinematics [RTK], and the like) loses power disabling the ability of the utility locator to determine geolocations. Likewise, when a battery dies in known utility locator devices, the inertial navigation sensors may also lose power disabling the utility locator device's ability to determine heading and other pose information relating to the orientation of utility locator device in three dimensions at its geolocation in the world frame. As a result, upon reboot, the mapping of utility lines may be discontinuous or otherwise be of inadequate quality.

Accordingly, there is a need in the art to address the above-described as well as other problems.

### SUMMARY

The disclosure relates generally to methods and apparatus for swapping batteries in complex bootable electronic devices that avoid unnecessary interruptions. More specifically, but not exclusively, the disclosure relates to methods and apparatus for swapping batteries in utility locator devices and other complex bootable electronic devices that avoid unnecessary interruptions and automatically restoring such devices to a fully operational state when a charged battery is installed.

In one aspect, the present disclosure relates to a battery swapping apparatus for use in complex bootable electronic devices. The battery swapping apparatus includes a removeable battery and a circuit or other element to detect the removal of the battery referred to herein as a “battery presence detection element.” Further, the battery swapping apparatus includes a memory element having one or more non-transitory memories to continually store the most recent operation settings of the complex bootable electronic device. The battery swapping apparatus further includes a processing element to, upon reinstallation of a charged battery, repower the device and reload the most recently stored operation settings of the complex bootable electronic device.

In another aspect, the present disclosure relates to a battery swapping apparatus for use in complex bootable electronic devices. The battery swapping apparatus includes a removeable battery and a battery presence detection element to detect the removal of the battery. Further, the battery swapping apparatus includes a memory element having one or more non-transitory memories to continually store the most recent operation settings of the complex bootable electronic device. The battery swapping apparatus includes a circuit or other element to determine the remaining power capacity powering the complex bootable electronic device referred to herein as a “capacitance measurement element.” For instance, the capacitance measurement element may be or include a predetermined measure of time or a measurement that occurs at each instance a battery is removed expressed as a measure of power or estimated time that the complex bootable electronic device may maintain the standby mode. Further, the complex bootable electronic device includes a processing element to switch the complex bootable electronic device into the standby mode when the battery is removed and restoring the most recent stored operation settings of the complex bootable electronic device when a charged battery is reinstalled prior to depletion of the remaining internal capacitance determined via the capacitance measurement element.

In another aspect, the present disclosure relates to a battery swapping method for use with a battery swapping apparatus. The method includes storing, via a memory element, the most recent operation settings of the complex bootable electronic device and detecting, via a battery presence detection element, the removal of a battery. Further, the method includes replacing the battery, automatically restarting the device, restoring the most recent stored operation settings of the complex bootable electronic device, and returning the device to a fully operational state.

In another aspect, the present disclosure relates to a battery swapping method for use with a battery swapping apparatus. The method includes storing, via a memory element, the most recent operation settings of the complex bootable electronic device and detecting, via a battery presence detection element, the removal of a battery. Further, the method includes entering the complex bootable device into a standby mode that includes halting power to non-critical processing and other powered elements of the device. The method further includes replacing the battery prior to depleting the remaining power capacity powering the complex bootable electronic device and automatically restarting the complex bootable electronic device. The method further includes restoring the most recent operation settings of the complex bootable electronic device prior to the removal of the battery, returning the device to its fully operational state. It should be noted that the fully operational state is substantially the same as that just prior to when the battery was removed.

Additional aspects, features, and functionality are further described below in conjunction with the appended drawings.

### BRIEF DESCRIPTION OF THE DRAWINGS

The present disclosure may be more fully appreciated in connection with the following detailed description taken in conjunction with the accompanying drawings, wherein:

FIG. 1 is a prior art illustration of GNSS receiver;

FIG. 2 is a diagram of a battery swapping apparatus;

FIG. 3 is a battery swapping method;

FIG. 4A is a diagram of another battery swapping apparatus;

FIG. 4B is a diagram of the battery swapping apparatus from FIG. 4A;

FIG. 5A is a diagram of another battery swapping apparatus;

FIG. 5B is a diagram of the battery swapping apparatus from FIG. 5A;

FIG. 6 is another battery swapping method;

FIG. 7 is an illustration of a utility locating system including a utility locator device;

FIG. 8A is a diagram of another battery swapping apparatus in a utility locator device;

FIG. 8B is a diagram of the battery swapping apparatus in a utility locator device from FIG. 8A;

FIG. 9 is a combined utility locating and mapping method and battery swapping method; and

FIG. 10 is an illustration of a utility locating system including a utility locator device self-standing via a tripod mechanism.

### DETAILED DESCRIPTION OF EMBODIMENTS

### Overview

The disclosure relates generally to methods and apparatus for swapping batteries in complex bootable electronic devices that avoid unnecessary interruptions. More specifically, but not exclusively, the disclosure relates to methods and apparatus for swapping batteries in utility locator devices and other complex bootable electronic devices that avoid unnecessary interruptions and automatically restoring such devices to a fully operational state when a charged battery is installed.

In one aspect, the present disclosure relates to a battery swapping apparatus for use in complex bootable electronic devices. The battery swapping apparatus includes a removeable battery which is typically rechargeable and a circuit or other element to detect the removal of the battery referred to herein as a “battery presence detection element.” Further, the battery swapping apparatus includes a memory element having one or more non-transitory memories to continually store the most recent operation settings of the complex bootable electronic device. The battery swapping apparatus further including a processing element to, upon reinstallation of a charged battery, repower the device and reload the most recently stored operation settings of the complex bootable electronic device.

In another aspect, the present disclosure relates to another battery swapping apparatus for use in complex bootable electronic devices. The battery swapping apparatus includes a battery presence detection element to detect the removal of the battery. Further, the battery swapping apparatus includes a memory element having one or more non-transitory memories to continually store the most recent operation settings of the complex bootable electronic device prior to the removal of the battery. The battery swapping apparatus includes a circuit or other element to determine the remaining power capacity powering the complex bootable electronic device referred to herein as a “capacitance measurement element.” For instance, the capacitance measurement element may be or include a predetermined measure of time that the complex bootable electronic device may maintain the standby mode. In some embodiments, the battery swapping apparatus may optionally include a secondary power element to provide electrical power to the complex bootable electronic device when the primary battery is removed. The secondary power element may, for instance, include one or more batteries, one or more supercapacitors or other electrochemical double layer capacitors (EDLCs), or the like to briefly power the complex bootable electronic device or select elements of the complex bootable electronic device to maintain in a standby mode. In some embodiments, the capacitance measurement element may optionally include a clock to estimate a runtime until the remaining power capacity will be depleted. Optionally, an alarm element may be included to alert a user of the imminent depletion of the remaining power capacity or a secondary power source. Further, the complex bootable electronic device includes a processing element to switch all or select parts of the complex bootable electronic device into the standby mode when the battery is removed and restoring the most recently stored operation settings of the complex bootable electronic device when a charged battery is reinstalled prior to depletion of the remaining internal capacitance determined via the capacitance measurement element.

The battery swapping apparatus may be included in a utility locator device configured to locate and map utility lines which may be buried in the ground. The utility locator device including a battery swapping apparatus may further have one or more antennas and associated receiver circuitry to determine positions of and map buried utility lines.

In another aspect, the present disclosure relates to a battery swapping method for use with a battery swapping apparatus. The method includes storing, via a memory element, the most recent operation settings of the complex bootable electronic device and detecting, via a battery presence detection element, the removal of a battery. Further, the method includes replacing the battery, automatically restarting the device, restoring the most recent stored operation settings of the complex bootable electronic device, and returning the device to its fully operational state.

In another aspect, the present disclosure relates to a battery swapping method for use with a battery swapping apparatus. The method includes storing, via a memory element, the most recent operation settings of the complex bootable electronic device and detecting, via a battery presence detection element, the removal of a battery. Further, the method includes entering the complex bootable device into a standby mode that includes halting power to non-critical processing and other powered elements of the device. Optionally, the method may include powering the complex bootable electronic device via a secondary power source (e.g., one or more batteries, supercapacitors or EDLCs, and the like) when the battery is removed. Optionally, a clock may estimate the runtime of the remaining power capacity powering the complex bootable electronic device. In another optional step, the method may include alerting the user of the imminent depletion of the remaining power capacity or a secondary power source. The method further includes replacing the battery prior to depleting the remaining power capacity powering the complex bootable electronic device and automatically restarting the complex bootable electronic device. The method further includes restoring the most recent operation settings of the complex bootable electronic device prior to the removal of the battery, returning the device to its fully operational state. It should be noted that the fully operational state is substantially the same as that just prior to when the battery was removed.

In some method embodiments, the battery swapping method may be used in a combined utility locating method. For instance, power may temporarily be halted to select elements of a utility locator device upon removal of a battery and the remaining internal capacitance and/or a secondary power source may keep vital and other elements requiring a boot process powered while the battery is swapped for a charged battery to prevent unnecessary disruptions to the workflow and locating/utility mapping procedure. In such a method, for instance, the battery swapping apparatus and method may store operational setting and maintain those settings related to, for instance, GNSS tracking and geolocation fix, INS data including heading information, IPPS (one pulse-per-second) and other phase locked circuits and elements, and the like.

Details of example devices, systems, and methods that may be combined with system, devices, and method embodiments herein, as well as additional components, methods, and configurations that may be used in conjunction with the embodiments described herein, are disclosed in co-assigned patents and patent applications including: U.S. Pat. No. 5,939,679, issued Aug. 17, 1999, entitled VIDEO PUSH CABLE; U.S. Pat. No. 6,545,704, issued Apr. 8, 2003, entitled VIDEO PIPE INSPECTION DISTANCE MEASURING SYSTEM; U.S. Pat. No. 6,697,102, issued Feb. 24, 2004, entitled BORE HOLE CAMERA WITH IMPROVED FORWARD AND SIDE VIEW ILLUMINATION; U.S. Pat. No. 6,831,679, issued Dec. 14, 2004, entitled VIDEO CAMERA HEAD WITH THERMAL FEEDBACK LIGHTING CONTROL; U.S. Pat. No. 6,862,945, issued Mar. 8, 2005, entitled CAMERA GUIDE FOR VIDEO PIPE INSPECTION SYSTEM; U.S. Pat. No. 6,908,310, issued Jun. 21, 2005, entitled SLIP RING ASSEMBLY WITH INTEGRAL POSITION ENCODER; U.S. Pat. No. 6,958,767, issued Oct. 25, 2005, entitled VIDEO PIPE INSPECTION SYSTEM EMPLOYING NON-ROTATING CABLE STORAGE DRUM; U.S. Pat. No. 7,009,399, issued Mar. 7, 2006, entitled OMNIDIRECTIONAL SONDE AND LINE LOCATOR; U.S. Pat. No. 7,221,136, issued May 22, 2007, entitled SONDES FOR LOCATING UNDERGROUND PIPES AND CONDUITS; U.S. Pat. No. 7,276,910, issued Oct. 2, 2007, entitled A COMPACT SELF-TUNED ELECTRICAL RESONATOR FOR BURIED OBJECT LOCATOR APPLICATIONS; U.S. Pat. No. 7,288,929, issued Oct. 30, 2007, entitled INDUCTIVE CLAMP FOR APPLYING SIGNAL TO BURIED UTILITIES; U.S. Pat. No. 7,332,901, issued Feb. 19, 2008, entitled LOCATOR WITH APPARENT DEPTH INDICATION; U.S. Pat. No. 7,443,154, issued Oct. 28, 2008, entitled MULTI-SENSOR MAPPING OMNIDIRECTIONAL SONDE AND LINE LOCATOR; U.S. Pat. No. 7,336,078, issued Feb. 26, 2008, entitled MULTI-SENSOR MAPPING OMNIDIRECTIONAL SONDE AND LINE LOCATORS; U.S. Pat. No. 7,557,559, issued Jul. 7, 2009, entitled COMPACT LINE ILLUMINATOR FOR BURIED PIPES AND CABLES; U.S. Pat. No. 7,741,848, issued Jun. 22, 2010, entitled ADAPTIVE MULTICHANNEL LOCATOR SYSTEM FOR MULTIPLE PROXIMITY DETECTION; U.S. Pat. No. 7,864,980, issued Jan. 4, 2011, entitled SONDES FOR LOCATING UNDERGROUND PIPES AND CONDUITS; U.S. Pat. No. 8,013,610, issued Sep. 6, 2011, entitled HIGH Q SELF-TUNING LOCATING TRANSMITTER; U.S. Pat. No. 8,289,385, issued Oct. 16, 2012, entitled PUSH-CABLE FOR PIPE INSPECTION SYSTEM; U.S. Pat. No. 8,264,226, issued Sep. 11, 2012, entitled SYSTEM AND METHOD FOR LOCATING BURIED PIPES AND CABLES WITH A MAN PORTABLE LOCATOR AND A TRANSMITTER IN A MESH NETWORK; U.S. patent application Ser. No. 13/769,202, filed Feb. 15, 2013, entitled SMART PAINT STICK DEVICES AND METHODS; U.S. Pat. No. 8,395,661, issued Mar. 12, 2013, entitled PIPE INSPECTION SYSTEM WITH SELECTIVE IMAGING CAPTURE; U.S. Pat. No. 8,400,154, issued Mar. 19, 2013, entitled LOCATOR ANTENNA WITH CONDUCTIVE BOBBIN; U.S. patent application Ser. No. 14/027,027, filed Sep. 13, 2013, entitled SONDE DEVICES INCLUDING A SECTIONAL FERRITE CORE STRUCTURE; U.S. Pat. No. 8,547,428, issued Oct. 1, 2013, entitled PIPE MAPPING SYSTEM; U.S. Pat. No. 8,587,648, issued Nov. 19, 2013, entitled SELF-LEVELING CAMERA HEAD; U.S. Pat. No. 8,908,027, issued Dec. 9, 2014, entitled ASYMMETRIC DRAG FORCE BEARING FOR USE WITH PUSH-CABLE STORAGE DRUM; U.S. Pat. No. 8,970,211, issued Mar. 3, 2015, entitled PIPE INSPECTION CABLE COUNTER AND OVERLAY MANAGEMENT SYSTEM; U.S. Pat. No. 9,057,754, issued Jun. 16, 2015, entitled ECONOMICAL MAGNETIC LOCATOR APPARATUS AND METHOD; U.S. Pat. No. 9,066,446, issued Jun. 23, 2015, entitled THERMAL EXTRACTION ARCHITECTURE FOR CAMERA HEADS, INSPECTION SYSTEMS, AND OTHER DEVICES AND SYSTEMS; U.S. Pat. No. 9,081,109, issued Jul. 14, 2015, entitled GROUND-TRACKING DEVICES FOR USE WITH A MAPPING LOCATOR; U.S. Pat. No. 9,082,269, issued Jul. 14, 2015, entitled HAPTIC DIRECTIONAL FEEDBACK HANDLES FOR LOCATION DEVICES; U.S. Pat. No. 9,080,992, issued Jul. 14, 2015, entitled ADJUSTABLE VARIABLE RESOLUTION INSPECTION SYSTEMS AND METHODS; U.S. Pat. No. 9,207,350, issued Dec. 8, 2015, entitled BURIED OBJECT LOCATOR APPARATUS WITH SAFETY LIGHTING ARRAY; U.S. Pat. No. 9,222,809, issued Dec. 29, 2015, entitled PORTABLE PIPE INSPECTION SYSTEMS AND APPARATUS; U.S. Pat. No. 9,341,740, issued May 17, 2016, entitled OPTICAL GROUND TRACKING APPARATUS, SYSTEMS, AND METHODS; U.S. Pat. No. 9,411,067, issued Aug. 9, 2016, entitled GROUND-TRACKING SYSTEMS AND APPARATUS; U.S. Pat. No. 9,435,907, issued Sep. 6, 2016, entitled PHASE SYNCHRONIZED BURIED OBJECT LOCATOR APPARATUS, SYSTEMS, AND METHODS; U.S. Pat. No. 9,448,376, issued Sep. 20, 2016, entitled HIGH BANDWIDTH PUSH-CABLES FOR VIDEO PIPE INSPECTION SYSTEMS; U.S. Pat. No. 9,465,129, issued Oct. 11, 2016, entitled IMAGE-BASED MAPPING LOCATING SYSTEM; U.S. Pat. No. 9,468,954, issued Oct. 18, 2016, entitled PIPE INSPECTION SYSTEM WITH JETTER PUSH-CABLE; U.S. Pat. No. 9,477,147, issued Oct. 25, 2016, entitled SPRING ASSEMBLIES WITH VARIABLE FLEXIBILITY FOR USE WITH PUSH-CABLES AND PIPE INSPECTION SYSTEMS; U.S. Pat. No. 9,521,303, issued Dec. 13, 2016, entitled CABLE STORAGE DRUM WITH MOVABLE CCU DOCKING APPARATUS; U.S. Pat. No. 9,523,788, issued Dec. 20, 2016, entitled MAGNETIC SENSING BURIED OBJECT LOCATOR INCLUDING A CAMERA; U.S. Pat. No. 9,571,326, issued Feb. 14, 2017, entitled METHOD AND APPARATUS FOR HIGH-SPEED DATA TRANSFER EMPLOYING SELF-SYNCHRONIZING QUADRATURE AMPLITUDE MODULATION (QAM); U.S. Pat. No. 9,599,449, issued Mar. 21, 2017, entitled SYSTEMS AND METHODS FOR LOCATING BURIED OR HIDDEN OBJECTS USING SHEET CURRENT FLOW MODELS; U.S. Pat. No. 9,599,740, issued Mar. 21, 2017, entitled USER INTERFACES FOR UTILITY LOCATORS; U.S. Pat. No. 9,625,602, issued Apr. 18, 2017, entitled SMART PERSONAL COMMUNICATION DEVICES AS USER INTERFACES; U.S. Pat. No. 9,632,199, issued Apr. 25, 2017, entitled INDUCTIVE CLAMP DEVICES, SYSTEMS, AND METHODS; U.S. Pat. No. 9,634,878, issued Apr. 25, 2017, entitled SYSTEMS AND METHODS FOR DATA TRANSFER USING SELF-SYNCHRONIZING QUADRATURE AMPLITUDE MODULATION (QAM); United States patent application, filed Apr. 25, 2017, entitled SYSTEMS AND METHODS FOR LOCATING AND/OR MAPPING BURIED UTILITIES USING VEHICLE-MOUNTED LOCATING DEVICES; U.S. Pat. No. 9,638,824, issued May 2, 2017, entitled QUAD-GRADIENT COILS FOR USE IN LOCATING SYSTEMS; United States patent application, filed May 9, 2017, entitled BORING INSPECTION SYSTEMS AND METHODS; U.S. Pat. No. 9,651,711, issued May 16, 2017, entitled HORIZONTAL BORING INSPECTION DEVICE AND METHODS; U.S. Pat. No. 9,684,090, issued Jun. 20, 2017, entitled NULLED-SIGNAL LOCATING DEVICES, SYSTEMS, AND METHODS; U.S. patent application Ser. No. 15/670,845, filed Aug. 7, 2016, entitled HIGH FREQUENCY AC-POWERED DRAIN CLEANING AND INSPECTION APPARATUS & METHODS; U.S. Pat. No. 9,746,572, issued Aug. 29, 2017, entitled ELECTRONIC MARKER DEVICES AND SYSTEMS; U.S. Pat. No. 9,769,366, issued Sep. 19, 2017, entitled SELF-GROUNDING TRANSMITTING PORTABLE CAMERA CONTROLLER FOR USE WITH PIPE INSPECTION SYSTEMS; U.S. Pat. No. 9,784,837, issued Oct. 10, 2017, entitled OPTICAL GROUND TRACKING APPARATUS, SYSTEMS & METHODS; U.S. Pat. No. 9,835,564, issued Dec. 5, 2017, entitled MULTI-CAMERA PIPE INSPECTION APPARATUS, SYSTEMS, AND METHODS; U.S. patent application Ser. No. 15/846,102, filed Dec. 18, 2017, entitled SYSTEMS AND METHOD FOR ELECTRONICALLY MARKING, LOCATING AND VIRTUALLY DISPLAYING BURIED UTILITIES; U.S. patent application Ser. No. 15/866,360, filed Jan. 9, 2018, entitled TRACKED DISTANCE MEASURING DEVICES, SYSTEMS, AND METHODS; U.S. Pat. No. 9,891,337, issued Feb. 13, 2018, entitled UTILITY LOCATOR TRANSMITTER DEVICES, SYSTEMS, and METHODS WITH DOCKABLE APPARATUS; U.S. Pat. No. 9,927,368, issued Mar. 27, 2018, entitled SELF-LEVELING INSPECTION SYSTEMS AND METHODS; U.S. Pat. No. 9,927,545, issued Mar. 27, 2018, entitled MULTI-FREQUENCY LOCATING SYSTEMS & METHODS; U.S. Pat. No. 9,928,613, issued Mar. 27, 2018, entitled GROUND TRACKING APPARATUS, SYSTEMS, AND METHODS; U.S. patent application Ser. No. 15/250,666, filed Mar. 27, 2018, entitled PHASE-SYNCHRONIZED BURIED OBJECT TRANSMITTER AND LOCATOR METHODS AND APPARATUS; U.S. Pat. No. 10,001,425, issued Jun. 19, 2018, entitled PORTABLE CAMERA CONTROLLER PLATFORM FOR USE WITH PIPE INSPECTION SYSTEM; U.S. Pat. No. 10,009,582, issued Jun. 26, 2018, entitled PIPE INSPECTION SYSTEM WITH REPLACEABLE CABLE STORAGE DRUM; U.S. Pat. No. 10,042,072, issued Aug. 7, 2018, entitled OMNI-INDUCER TRANSMITTING DEVICES AND METHODS; U.S. patent application Ser. No. 16/049,699, filed Jul. 30, 2018, entitled OMNI-INDUCER TRANSMITTING DEVICES AND METHODS; U.S. Pat. No. 10,073,186, issued Sep. 11, 2018, entitled KEYED CURRENT SIGNAL UTILITY LOCATING SYSTEMS AND METHODS; U.S. Pat. No. 10,105,723, issued Oct. 23, 2018, entitled TRACKABLE DIPOLE DEVICES, METHODS, AND SYSTEMS FOR USE WITH MARKING PAINT STICKS; U.S. Pat. No. 10,162,074, issued Dec. 25, 2018, entitled UTILITY LOCATORS WITH RETRACTABLE SUPPORT STRUCTURES AND APPLICATIONS THEREOF; United States patent application, filed Dec. 31, 2018, entitled ADJUSTABLE VARIABLE RESOLUTION INSPECTION SYSTEMS AND METHODS; U.S. patent application Ser. No. 16/241,864, filed Jan. 7, 2019, entitled TRACKED DISTANCE MEASURING DEVICES, SYSTEMS, AND METHODS; U.S. patent application Ser. No. 16/255,524, filed Jan. 23, 2019, entitled RECHARGEABLE BATTERY PACK ONBOARD CHARGE STATE INDICATION METHODS AND APPARATUS; U.S. patent application Ser. No. 16/382,136, filed Apr. 11, 2019, entitled GEOGRAPHIC MAP UPDATING METHODS AND SYSTEMS; U.S. Pat. No. 10,274,632, issued Apr. 20, 2019, entitled UTILITY LOCATING SYSTEMS WITH MOBILE BASE STATION; U.S. Pat. No. 10,288,997, issued May 14, 2019, entitled ROTATING CONTACT ASSEMBLIES FOR SELF-LEVELING CAMERA HEADS; U.S. patent application Ser. No. 29/692,937, filed May 29, 2019, entitled BURIED OBJECT LOCATOR; U.S. patent application Ser. No. 16/443,789, filed Jun. 17, 2019, entitled MULTI-DIELECTRIC COAXIAL PUSH-CABLES AND ASSOCIATED APPARATUS; U.S. patent application Ser. No. 16/449,187, filed Jun. 21, 2019, entitled ELECTROMAGNETIC MARKER DEVICES FOR BURIED OR HIDDEN USE; U.S. Pat. No. 10,353,103, issued Jul. 16, 2019, entitled SELF-STANDING MULTI-LEG ATTACHMENT DEVICES FOR USE WITH UTILITY LOCATORS; U.S. Pat. No. 10,401,526, issued Sep. 3, 2019, entitled BURIED UTILITY MARKER DEVICES, SYSTEMS, AND METHODS; U.S. Pat. No. 10,371,305, issued Aug. 6, 2019, entitled DOCKABLE TRIPODAL CAMERA CONTROL UNIT; U.S. patent application Ser. No. 16/559,576, filed Sep. 3, 2019, entitled VIDEO PIPE INSPECTION SYSTEMS WITH VIDEO INTEGRATED WITH ADDITIONAL SENSOR DATA; U.S. patent application Ser. No. 16/680,383, filed Nov. 11, 2019, entitled HEAT EXTRACTION ARCHITECTURE FOR COMPACT VIDEO CAMERA HEADS; U.S. patent application Ser. No. 16/676,292, filed Nov. 6, 2019, entitled ROBUST IMPEDANCE CONTROLLED SLIP RINGS; U.S. patent application Ser. No. 16/687,057, filed Nov. 18, 2019, entitled PIPE INSPECTION AND/OR MAPPING CAMERA HEADS, SYSTEMS, AND METHODS; U.S. patent application Ser. No. 16/701,085, filed Dec. 2, 2019, entitled MAP GENERATION BASED ON UTILITY LINE POSITION AND ORIENTATION ESTIMATES; U.S. Patent Application 62/943,164, filed Dec. 3, 2019, entitled INTEGRAL DUAL CLEANER CAMERA DRUM SYSTEMS AND METHODS; U.S. Pat. No. 10,555,086, issued Feb. 4, 2020, entitled MAGNETIC FIELD CANCELING AUDIO SPEAKERS FOR USE WITH BURIED UTILITY LOCATORS OR OTHER DEVICES; U.S. Pat. No. 10,557,824, issued Feb. 11, 2020, entitled RESILIENTLY DEFORMABLE MAGNETIC FIELD TRANSMITTER CORES FOR USE WITH UTILITY LOCATING DEVICES AND SYSTEMS; U.S. Pat. No. 10,564,309, issued Feb. 18, 2020, entitled SYSTEMS AND METHODS FOR UNIQUELY IDENTIFYING BURIED UTILITIES IN A MULTI-UTILITY ENVIRONMENT; U.S. Pat. No. 10,569,952, issued Feb. 25, 2020, entitled MARKING PAINT APPLICATOR FOR USE WITH PORTABLE UTILITY LOCATOR; U.S. Provisional Patent Application 62/984,768, filed Mar. 3, 2020, entitled DOCKABLE CAMERA REEL AND CCU SYSTEM; U.S. patent application Ser. No. 16/810,788, filed Mar. 5, 2019, entitled MAGNETICALLY RETAINED DEVICE HANDLES; U.S. patent application Ser. No. 16/833,426, filed Mar. 27, 2020, entitled LOW COST, HIGH PERFORMANCE SIGNAL PROCESSING IN A MAGNETIC-FIELD SENSING BURIED UTILITY LOCATOR SYSTEM; U.S. Pat. No. 10,608,348, issued Mar. 31, 2020, entitled DUAL ANTENNA SYSTEMS WITH VARIABLE POLARIZATION; U.S. Provisional Patent Application 63/012,480, filed Apr. 20, 2020, entitled UTILITY LOCATING DEVICES EMPLOYING MULTIPLE SPACED APART GNSS ANTENNAS; U.S. Provisional Patent Application 63/015,692, filed Apr. 27, 2020, entitled SPATIALLY AND PROCESSING-BASED DIVERSE REDUNDANCY FOR RTK POSITIONING; U.S. Pat. No. 10,670,766, issued Jun. 2, 2020, entitled UTILITY LOCATING SYSTEMS, DEVICES, AND METHODS USING RADIO BROADCAST SIGNALS; U.S. Pat. No. 10,690,795, issued Jun. 23, 2020, entitled LOCATING DEVICES, SYSTEMS, AND METHODS USING FREQUENCY SUITES FOR UTILITY DETECTION; U.S. patent application Ser. No. 16/908,625, filed Jun. 22, 2020, entitled ELECTROMAGNETIC MARKER DEVICES WITH SEPARATE RECEIVE AND TRANSMIT ANTENNA ELEMENTS; U.S. patent application Ser. No. 16/921,775, filed Jul. 6, 2020, entitled AUTO-TUNING CIRCUIT APPARATUS AND METHODS; U.S. Pat. No. 8,587,648, issued Jul. 14, 2020, entitled SELF-LEVELING CAMERA HEADS; U.S. Provisional Patent Application 63/055,278, filed Jul. 22, 2020, entitled VEHICLE-BASED UTILITY LOCATING USING PRINCIPAL COMPONENTS; U.S. Provisional Patent Application 63/063,151, filed Aug. 7, 2020, INSPECTION SYSTEM PUSH-CABLE GUIDE APPARATUS; U.S. Pat. No. 10,764,541, issued Sep. 1, 2020, entitled COAXIAL VIDEO PUSH-CABLES FOR USE IN INSPECTION SYSTEMS; U.S. patent application Ser. No. 17/014,646, filed Sep. 8, 2020, entitled INTEGRATED FLEX-SHAFT CAMERA SYSTEM WITH HAND CONTROL; U.S. patent application Ser. No. 16/588,834, issued Sep. 9, 2019, entitled VIDEO INSPECTION SYSTEM WITH WIRELESS ENABLED CABLE STORAGE DRUM; U.S. Pat. No. 10,777,919, issued Sep. 15, 2020, entitled MULTIFUNCTION BURIED UTILITY LOCATING CLIPS; U.S. patent application Ser. No. 17/020,487, filed Sep. 14, 2020, entitled ANTENNA SYSTEMS FOR CIRCULARLY POLARIZED RADIO SIGNALS; U.S. Provisional Patent Application 63/091,67, filed Oct. 14, 2020, entitled ELECTRONIC MARKER-BASED NAVIGATION SYSTEMS AND METHODS FOR USE IN GNSS-DEPRIVED ENVIRONMENTS; U.S. Pat. No. 10,809,408, issued Oct. 20, 2020, entitled DUAL SENSED LOCATING SYSTEMS AND METHODS; U.S. patent application Ser. No. 17/087,554, filed Nov. 2, 2020, entitled PORTABLE PIPE INSPECTION SYSTEMS AND METHODS; U.S. Pat. No. 10,834,364, issued Nov. 10, 2020, entitled PORTABLE PIPE INSPECTION SYSTEMS AND METHODS; U.S. Pat. No. 10,841,144, issued Nov. 17, 2020, entitled SYSTEM AND METHODS FOR DATA TRANSFER USING SELF-SYNCHRONIZING QUADRATURE AMPLITUDE MODULATION (QAM); U.S. Pat. No. 10,845,497, issued Nov. 24, 2020, entitled PHASE-SYNCHRONIZED BURIED OBJECT TRANSMITTER AND LOCATOR METHODS AND APPARATUS; U.S. Pat. No. 10,848,655, issued Nov. 24, 2020, entitled HEAT EXTRACTION ARCHITECTURE FOR COMPACT VIDEO CAMERA HEADS; U.S. Pat. No. 10,855,950, issued Dec. 1, 2020, entitled HIGH BANDWIDTH VIDEO PUSH-CABLES FOR PIPE INSPECTION SYSTEMS; U.S. patent application Ser. No. 17/110,273, filed Dec. 2, 2020, entitled INTEGRAL DUAL CLEANER CAMERA DRUM SYSTEMS AND METHODS; U.S. Pat. No. 10,859,727, issued Dec. 8, 2020, entitled ELECTRONIC MARKER DEVICES AND SYSTEMS; U.S. Pat. No. 10,863,064, issued Dec. 8, 2020, entitled CABLE STORAGE DRUM WITH MOVEABLE CCU DOCKING APPARATUS; U.S. Pat. No. 10,907,690, issued Feb. 2, 2021, entitled PIPE INSPECTION SYSTEMS WITH ASSYMETRIC DRAG FORCE BEARINGS; U.S. Pat. No. 10,908,311, issued Feb. 2, 2021, entitled SELF-STANDING MULTI-LEG ATTACHMENT DEVICES FOR USE WITH UTILITY LOCATORS; U.S. Pat. No. 10,921,263, issued Feb. 16, 2021, entitled PIPE INSPECTION SYSTEM WITH JETTER PUSH-CABLE; U.S. patent application Ser. No. 17/182,113, filed Feb. 22, 2021, entitled VIDEO PIPE INSPECTION SYSTEMS; U.S. Pat. No. 10,928,538, issued Feb. 23, 2021, entitled KEYED CURRENT SIGNAL LOCATING SYSTEMS AND METHODS; U.S. Pat. No. 10,935,686, issued Mar. 2, 2021, entitled UTILITY LOCATING SYSTEM WITH MOBILE BASE STATION; U.S. patent application Ser. No. 17/190,400, filed Mar. 3, 2021, entitled DOCKABLE CAMERA REEL AND CCU SYSTEM; U.S. patent application Ser. No. 17/202,128, filed Mar. 15, 2021, entitled BORING INSPECTION SYSTEMS AND METHODS; U.S. Pat. No. 10,955,583, issued Mar. 23, 2021, entitled BORING INSPECTION SYSTEMS AND METHODS; U.S. Pat. No. 9,927,368, issued Mar. 27, 2021, entitled SELF-LEVELING INSPECTION SYSTEMS AND METHODS; U.S. Pat. No. 10,976,462, issued Apr. 13, 2021, entitled VIDEO INSPECTION SYSTEMS WITH PERSONAL COMMUNICATION DEVICE USER INTERFACES; U.S. Pat. No. 10,992,849, issued Apr. 27, 2021, entitled PIPE INSPECTION SYSTEMS WITH SELF-GROUNDING PORTABLE CAMERA CONTROLLERS; U.S. Pat. No. 11,016,381, issued May 25, 2021, entitled SPRING ASSEMBLIES WITH VARIABLE FLEXIBLE FOR USE WITH PUSH-CABLES AND PIPE INSPECTION SYSTEMS; U.S. patent application Ser. No. 17/397,940, filed Aug. 9, 2021, entitled INSPECTION SYSTEM PUSH-CABLE GUIDE APPARATUS; U.S. Pat. No. 11,088,890, issued Aug. 10, 2021, entitled VIDEO INSPECTION SYSTEMS AND METHODS USING SELF-SYNCHRONIZING QAM; U.S. Pat. No. 11,132,781, issued Sep. 28, 2021, entitled PIPE INSPECTION SYSTEM CAMERA HEADS; U.S. patent application Ser. No. 17/501,670, filed Oct. 14, 2021, entitled ELECTRONIC MARKER-BASED NAVIGATION SYSTEMS AND METHODS FOR USE IN GNSS-DEPRIVED ENVIRONMENTS; U.S. patent application Ser. No. 17/528,155, filed Nov. 16, 2021, entitled PORTABLE CAMERA CONTROLLER PLATFORM FPR USE WITH PIPE INSPECTION SYSTEMS; U.S. Pat. No. 11,178,317, issued Nov. 16, 2021, entitled HEAT EXTRACTION APPARATUS; U.S. patent application Ser. No. 17/528,956, filed Nov. 17, 2021, entitled VIDEO INSPECTION SYSTEM APPARATUS AND METHODS WITH RELAY MODULES AND CONNECTION PORTS; U.S. patent application Ser. No. 17/531,533, filed Nov. 19, 2021, entitled INPUT MULTIPLEXED SIGNAL PROCESSING APPARATUS AND METHODS; U.S. patent application Ser. No. 17/532,938, filed Nov. 22, 2021, entitled PIPE INSPECTION AND/OR MAPPING CAMERA HEADS, SYSTEMS, AND METHODS; U.S. Pat. No. 11,187,822, issued Nov. 30, 2021, entitled SONDE DEVICES INCLUDING SECTIONAL FERRITE CORE STRUCTURE; U.S. Pat. No. 11,187,971, issued Nov. 30, 2021, entitled ROTATING CONTACT ASSEMBLIES FOR SELF-LEVELING CAMERA HEADS; U.S. patent application Ser. No. 17/541,057, filed Dec. 2, 2021, entitled COLOR-INDEPENDENT MARKER DEVICE APPARATUS, METHODS, AND SYSTEMS; U.S. patent application Ser. No. 17/541,057, filed Dec. 2, 2021, entitled VIDEO INSPECTION SYSTEM, APPARATUS, AND METHODS WITH RELAY MODULES AND CONNECTION PORTCOLOR-INDEPENDENT MARKER DEVICE APPARATUS, METHODS, AND SYSTEMS; U.S. Pat. No. 11,193,767, issued Dec. 7, 2021, entitled SMART PAINT STICK DEVICES AND METHODS; U.S. Pat. No. 11,199,510, issued Dec. 14, 2021, entitled PIPE INSPECTION AND CLEANING APPARATUS AND SYSTEMS; U.S. Pat. No. 11,209,115, issued Dec. 28, 2021, entitled PIPE INSPECTION AND/OR MAPPING CAMERA HEADS, SYSTEMS, AND METHODS; U.S. Pat. No. 11,209,334, issued Dec. 28, 2021, entitled PORTABLE CAMERA CONTROLLER PLATFORM FOR USE WITH PIPE INSPECTION SYSTEMS; U.S. patent application Ser. No. 17/563,049, filed Dec. 28, 2021, entitled SONDE DEVICES WITH A SECTIONAL FERRITE CORE; U.S. patent application Ser. No. 17/687,538, filed Mar. 4, 2022, entitled ANTENNAS, MULTI-ANTENNA APPARATUS, AND ANTENNA HOUSINGS; U.S. Pat. No. 11,280,934, issued Mar. 22, 2022, entitled ELECTROMAGNETIC MARKER DEVICES FOR BURIED OR HIDDEN USE; U.S. Pat. No. 11,300,597, issued Apr. 12, 2022, entitled SYSTEMS AND METHODS FOR LOCATING AND/OR MAPPING BURIED UTILITIES USING VEHICLE-MOUNTED LOCATING DEVICES; U.S. Pat. No. 11,300,700, issued Apr. 12, 2022, entitled SYSTEM AND METHODS OF USING A SONDE DEVICE WITH A SECTIONAL FERRITE CORE STRUCTURE; U.S. patent application Ser. No. 17/845,290, filed Jun. 21, 2022, entitled DAYLIGHT VISIBLE AND MULTI-SPECTRAL LASER RANGEFINDERS AND ASSOCIATED SYSTEMS AND METHODS AND UTILITY LOCATOR DEVICES; U.S. patent application Ser. No. 17/868,709, filed Jul. 19, 2022, entitled INSPECTION CAMERA DEVICES AND METHODS; U.S. patent application Ser. No. 17/815,387, filed Jul. 27, 2022, entitled INWARD SLOPED DRUM FACE FOR PIPE INSPECTION CAMERA SYSTEM; U.S. Pat. No. 11,402,337, issued Aug. 2, 2022, entitled VIDEO PIPE INSPECTION SYSTEMS WITH VIDEO INTEGRATED WITH ADDITIONAL SENSOR DATA; U.S. Pat. No. 11,418,761, issued Aug. 16, 2022, entitled INSPECTION CAMERA DEVICES AND METHODS WITH SELECTIVELY ILLUMINATED MULTISENSOR IMAGING; U.S. Pat. No. 11,448,600, issued Sep. 20, 2022, entitled MULTI-CAMERA PIPE INSPECTION APPARATUS, SYSTEMS, AND METHODS; U.S. patent application Ser. No. 17/993,784, filed Nov. 23, 2022, entitled VIDEO PIPE INSPECTION SYSTEMS; U.S. Pat. No. 11,528,401, issued Dec. 13, 2022, entitled PIPE INSPECTION SYSTEMS WITH SELF-GROUNDING PORTABLE CAMERA CONTROLLERS; U.S. patent application Ser. No. 18/091,079, filed Dec. 29, 2022, entitled VIDEO INSPECTION SYSTEMS WITH WIRELESS ENABLED DRUM; U.S. patent application Ser. No. 18/148,850, filed Dec. 30, 2022, entitled SPRING ASSEMBLIES WITH VARIABLE FLEXIBILITY FOR USE WITH PUSH-CABLES AND PIPE INSPECTION SYSTEMS; U.S. Pat. No. 11,550,214, issued Jan. 10, 2023, entitled SPRING ASSEMBLIES WITH VARIABLE FLEXIBLE FOR USE WITH PUSH-CABLES AND PIPE INSPECTION SYSTEMS; U.S. Pat. No. 11,558,537, issued Jan. 17, 2023, entitled VIDEO INSPECTION SYSTEM WITH WIRELESS ENABLED CABLE STORAGE DRUM; MODULAR BATTERY SYSTEMS INCLUDING INTERCHANGEABLE BATTERY INTERFACE APPARATUS; U.S. patent application Ser. No. 18/162,663, filed Jan. 31, 2023, entitled UTILITY LOCATING SYSTEMS AND METHODS WITH FILTER TUNING FOR POWER GRID FLUCTUATIONS; U.S. patent application Ser. No. 18/121,547, filed Mar. 14, 2023, entitled DOCKABLE CAMERA REEL AND CAMERA CONTROL UNIT (CCU) SYSTEM; U.S. patent application Ser. No. 18/121,562, filed Mar. 14, 2023, entitled PIPE INSPECTION AND CLEANING APPARATUS AND SYSTEMS; U.S. Provisional Patent Application 63/492,473, filed Mar. 27, 2023, entitled VIDEO INSPECTION AND CAMERA HEAD TRACKING SYSTEMS AND METHODS; U.S. Pat. No. 11,614,412, issued Mar. 28, 2023, entitled PIPE INSPECTION SYSTEMS WITH JETTER PUSH-CABLE; U.S. Pat. No. 11,614,613, issued Mar. 28, 2023, entitled DOCKABLE CAMERA REEL AND CCU SYSTEM; U.S. patent application Ser. No. 18/130,341, filed Apr. 3, 2023, entitled VIDEO PUSH-CABLES FOR PIPE INSPECTION SYSTEMS; U.S. Pat. No. 11,621,099, issued Apr. 4, 2023, entitled COAXIAL VIDEO PUSH-CABLES FOR USE IN INSPECTION SYSTEMS; U.S. patent application Ser. No. 18/135,661, filed Apr. 17, 2023, entitled VIDEO PIPE INSPECTION SYSTEMS AND METHODS WITH SENSOR DATA; U.S. patent application Ser. No. 18/140,488, filed Apr. 27, 2023, entitled INTEGRATED FLEX-SHAFT CAMERA SYSTEM; U.S. Pat. No. 11,639,990, issued May 2, 2023, entitled VIDEO PIPE INSPECTION SYSTEMS WITH VIDEO INTEGRATED WITH ADDITIONAL SENSOR DATA; U.S. Pat. No. 11,649,917, issued May 16, 2023, entitled INTEGRATED FLEX-SHAFT CAMERA SYSTEM WITH HAND CONTROL; U.S. patent application Ser. No. 18/203,029, filed May 29, 2023, entitled SELF-LEVELING INSPECTION SYSTEMS AND METHODS; U.S. Pat. No. 11,665,321, issued May 30, 2023, entitled PIPE INSPECTION SYSTEM WITH REPLACEABLE CABLE STORAGE DRUM; U.S. patent application Ser. No. 18/207,898, filed Jun. 9, 2023, entitled SONDE DEVICES WITH A SECTIONAL CORE; U.S. Pat. No. 11,674,906, issued Jun. 13, 2023, entitled SELF-LEVELING INSPECTION SYSTEMS AND METHODS; U.S. Pat. No. 11,686,878, issued Jun. 27, 2023, entitled ELECTRONIC MARKER DEVICES FOR BURIED OR HIDDEN USE; U.S. Provisional Patent Application 63/514,090, filed Jul. 17, 2023, entitled SMARTPHONE MAPPING APPARATUS FOR ASET TAGGING AS USED WITH UTILITY LOCATOR DEVICES; U.S. Pat. No. 11,709,289, issued Jul. 25, 2023, entitled SONDE DEVICES WITH A SECTIONAL FERRITE CORE; U.S. patent application Ser. No. 18/365,225, filed Aug. 3, 2023, entitled SYSTEMS AND METHODS FOR INSPECTION ANIMATION; U.S. Pat. No. 11,719,376, issued Aug. 8, 2023, entitled DOCKABLE TRIPODAL CAMERA CONTROL UNIT; U.S. Pat. No. 11,719,846, issued Aug. 8, 2023, entitled BURIED UTILITY LOCATING SYSTEMS WITH WIRELESS DATA COMMUNICATION INCLUDING DETERMINATION OF CROSS COUPLING TO ADJACENT UTILITIES; U.S. patent application Ser. No. 18/233,285, filed Aug. 11, 2023, entitled BURIED OBJECT LOCATOR; U.S. patent application Ser. No. 18/236,786, filed Aug. 22, 2023, entitled MAGNETIC UTILITY LOCATOR DEVICES AND METHODS; U.S. Pat. No. 11,747,505, issued Sep. 5, 2023, entitled MAGNETIC UTILITY LOCATOR DEVICES AND METHODS; U.S. patent application Ser. No. 18/368,510, filed Sep. 14, 2023, entitled MULTIFUNCTION BURIED UTILITY LOCATING CLIPS; U.S. patent application Ser. No. 18/365,203, filed Sep. 14, 2023, entitled SYSTEMS AND METHODS FOR ELECTRONICALLY MARKING, LOCATING AND VIRTUALLY DISPLAYING BURIED UTILITIES; U.S. Pat. No. 11,768,308, issued Sep. 26, 2023, entitled SYSTEMS AND METHODS FOR ELECTRONICALLY MARKING, LOCATING AND VIRTUALLY DISPLAYING BURIED UTILITIES; U.S. Pat. No. 11,769,956, issued Sep. 26, 2023, entitled MULTIFUNCTION BURIED UTILITY LOCATING CLIPS; U.S. Pat. No. 11,782,179, issued Oct. 10, 2023, entitled BURIED OBJECT LOCATOR WITH DODECAHEDRAL ANTENNA CONFIGURATION APPARATUS AND METHODS; U.S. Pat. No. 11,789,093, issued Oct. 17, 2023, entitled THREE-AXIS MEASUREMENT MODULES AND SENSING METHODS; U.S. Provisional patent application Ser. No. 18/490,763, filed Oct. 20, 2023, entitled LINKED CABLE-HANDLING AND CABLE-STORAGE DRUM DEVICES AND SYSTEMS FOR COORDINATED MOVEMENT OF PUSH-CABLE; U.S. Pat. No. 11,796,707, issued Oct. 24, 2023, entitled USER INTERFACES FOR UTILITY LOCATORS; U.S. Provisional Patent Application 63/599,890, filed Nov. 16, 2023, entitled VIDEO INSPECTION AND CAMERA HEAD TRACKING SYSTEMS AND METHODS; U.S. patent application Ser. No. 18/528,773, filed Dec. 4, 2023, entitled PIPE INSPECTION SYSTEM CAMERA HEAD; U.S. Pat. No. 11,842,474, issued Dec. 12, 2023, entitled PIPE INSPECTION SYSTEM CAMERA HEADS; U.S. patent application Ser. No. 18/539,265, filed Dec. 14, 2023, entitled INTEGRAL DUAL CLEANER DRUM SYSTEMS AND METHODS; U.S. patent application Ser. No. 18/539,268, filed Dec. 14, 2023, entitled HIGH FREQUENCY AC-POWERED DRAIN CLEANING AND INSPECTION APPARATUS AND METHODS; U.S. patent application Ser. No. 18/544,042, filed Dec. 18, 2023, entitled SYSTEMS, APPARATUS, AND METHODS FOR DOCUMENTING UTILITY POTHOLES AND ASSOCIATED UTILITY LINES; U.S. Pat. No. 11,846,095, issued Dec. 19, 2023, entitled HIGH FREQUENCY AC-POWERED DRAIN CLEANING AND INSPECTION APPARATUS & METHODS; U.S. Pat. No. 11,859,755, issued Jan. 2, 2024, entitled INTEGRAL DUAL CLEANER CAMERA DRUM SYSTEMS AND METHODS; U.S. patent application Ser. No. 18/412,452, filed Jan. 12, 2024, entitled MULTI-CAMERA APPARATUS FOR WIDE ANGLE PIPE INTERNAL INSPECTION; U.S. Pat. No. 11,876,283, issued Jan. 16, 2024, entitled COMBINED SATELLITE NAVIGATION AND RADIO TRANSCEIVER ANTENNA DEVICES; U.S. patent application Ser. No. 18/414,785, filed Jan. 17, 2024, entitled SONDE DEVICES; U.S. Pat. No. 11,879,852, issued Jan. 23, 2024, entitled MULTI-CAMERA APPARATUS FOR WIDE ANGLE PIPE INTERNAL INSPECTION; U.S. Pat. No. 11,880,005, issued Jan. 23, 2024, entitled SONDE DEVICES INCLUDING A SECTIONAL FERRITE CORE STRUCTURE; U.S. Provisional Patent Application 63/625,259, filed Jan. 25, 2024, entitled ACCESSIBLE DRUM-REEL FRAME FOR PIPE INSPECTION CAMERA SYSTEM; U.S. Pat. No. 11,894,707, issued Feb. 6, 2024, entitled RECHARGEABLE BATTERY PACK ONBOARD CHARGE STATE INDICATION METHODS AND APPARATUS; U.S. Provisional Patent Application 63/552,522, filed Feb. 12, 2024, entitled ACCESSIBLE DRUM-REEL FRAME FOR PIPE INSPECTION CAMERA SYSTEM; U.S. Pat. No. 11,909,104, issued Feb. 20, 2024, entitled ANTENNAS, MULTI-ANTENNA APPARATUS, AND ANTENNA HOUSINGS; U.S. Pat. No. 11,909,150, issued Feb. 20, 2024, entitled ROBUST IMPEDANCE CONTROLLED SLIP RINGS; U.S. Provisional Patent Application 63/558,098, filed Feb. 26, 2024, entitled SYSTEMS, DEVICES, AND METHODS FOR DOCUMENTING GROUND ASSETS AND ASSOCIATED UTILITY LINES; U.S. Pat. No. 11,921,225, issued Mar. 5, 2024, entitled ANTENNA SYSTEMS FOR CIRCULARLY POLARIZED RADIO SIGNALS; U.S. patent application Ser. No. 18/611,449, filed Mar. 20, 2024, entitled VIDEO INSPECTION AND CAMERA HEAD TRACKING SYSTEMS AND METHODS; U.S. patent application Ser. No. 18/611,449, issued Mar. 20, 2024, entitled VIDEO INSPECTION AND CAMERA HEAD TRACKING SYSTEMS AND METHODS; U.S. Pat. No. 11,953,643, issued Apr. 9, 2024, entitled MAP GENERATION BASED ON UTILITY LINE POSITION AND ORIENTATION ESTIMATES; U.S. Pat. No. 11,962,943, issued Apr. 16, 2024, entitled INSPECTION CAMERA DEVICES AND METHODS; U.S. Provisional Patent 63/643,915, filed May 7, 2024, entitled SYSTEMS AND METHODS FOR LOCATING AND MAPPING BURIED UTILITY OBJECTS USING ARTIFICIAL INTELLIGENCE WITH LOCAL OR REMOTE PROCESSING; U.S. Pat. No. 11,988,951, issued May 21, 2024, entitled MULTI-DIELECTRIC COAXIAL PUSH-CABLES AND ASSOCIATED APPARATUS; U.S. Provisional Patent 63/659,722, filed Jun. 13, 2024, entitled VEHICLE-MOUNTING DEVICES AND METHODS FOR USE IN VEHICLE-BASED LOCATING SYSTEMS; U.S. Provisional application Ser. No. 18/747,912, filed Jun. 19, 2024, entitled INNER DRUM MODULE WITH PUSH-CABLE INTERFACE FOR PIPE INSPECTION; U.S. Provisional application Ser. No. 18/758,937, filed Jun. 28, 2024, entitled FILTERING METHODS AND ASSOCIATED UTILITY LOCATOR DEVICES FOR LOCATING AND MAPPING BURIED UTILITY LINES; U.S. patent application Ser. No. 18/774,758, filed Jul. 16, 2024, entitled SMARTPHONE MOUNTING APPARATUS AND IMAGING METHODS FOR ASSET TAGGING AND UTILITY MAPPING AS USED WITH UTILITY LOCATING DEVICES; U.S. Provisional Patent 63/674,749, issued Jul. 23, 2024, entitled PIPE MAPPING FOR FEATURE AND ASSET RECOGNITION USING ARTIFICIAL INTELLIGENCE; U.S. Provisional Patent 63/692,642, issued Sep. 9, 2024, entitled ELECTRONIC MODULES AND ASSOCIATED SYSTEMS; U.S. Provisional Patent 63/694,102, issued Sep. 12, 2024, entitled METHODS AND APPARATUS FOR BATTERY SWAPPING IN UTILITY LOCATOR DEVICES AND OTHER COMPLEX BOOTABLE ELECTRONIC DEVICES; U.S. Provisional Patent 63/719,026, issued Nov. 11, 2024, entitled PUSH-CABLE WITH OFFSET JACKET EXTRUSION; U.S. Provisional Patent 63/726,858, issued Dec. 2, 2024, entitled DIGITAL SELF-LEVELING PIPE INSPECTION CAMERA SYSTEMS AND METHODS WITH AUTOMIC MAGNIFICATION; U.S. patent application Ser. No. 19/018,842, issued Jan. 13, 2025, entitled ACCESSIBLE DRUM-REEL FRAME FOR PIPE INSPECTION CAMERA SYSTEM; U.S. Provisional Patent Application 63/761,029, filed Feb. 20, 2025, entitled UTILITY LOCATING SYSTEMS, DEVICES, AND METHODS EMPLOYING SPATIAL AUDIO; U.S. patent application Ser. No. 19/059,288, filed Feb. 21, 2025, entitled SYSTEMS, DEVICES, AND METHODS FOR DOCUMENTING GROUND ASSETS AND ASSOCIATED UTILITY LINES; U.S. Provisional Patent Application 63/770,287, filed Mar. 11, 2025, entitled WORLD FRAME/LOCAL FRAME MAPPING AND RE-MAPPING IN A UTILITY LOCATION SYSTEM; U.S. Pat. No. 12,253,382, issued Mar. 18, 2025, entitled VEHICLE-BASED UTILITY LOCATING USING PRINCIPAL COMPONENTS; U.S. patent application Ser. No. 18/198,495, filed May 18, 2025, entitled SYSTEMS AND METHODS FOR LOCATING AND MAPPING BURIED UTILITY OBJECTS USING ARTIFICIAL INTELLIGENCE WITH LOCAL OR REMOTE PROCESSING; U.S. patent application Ser. No. 19/234,473, filed Jun. 11, 2025, entitled VEHICLE-MOUNTING DEVICES AND METHODS FOR USE IN VEHICLE-BASED LOCATING SYSTEMS; U.S. Pat. No. 12,360,251, issued Jul. 15, 2025, entitled GNSS POSITIONING METHODS AND DEVICES USING PPP-RTK, RTK, SSR, OR LIKE CORRECTION DATA; U.S. Pat. No. 12,360,282, issued Jul. 15, 2025, entitled NATURAL VOICE UTILITY ASSET ANNOTATION SYSTEM; U.S. Pat. No. 12,363,251, issued Jul. 15, 2025, entitled SYSTEMS AND METHODS FOR INSPECTION ANIMATION; U.S. patent application Ser. No. 19/274,389, filed Jul. 18, 2025, entitled PIPE MAPPING FOR FEATURE AND ASSET RECOGNITION USING ARTIFICIAL INTELLIGENCE; U.S. Pat. No. 12,368,944, issued Jul. 22, 2025, entitled INNER DRUM MODULE WITH PUSH-CABLE INTERFACE FOR PIPE INSPECTION; U.S. Pat. No. 12,364,875, issued Jul. 29, 2025, entitled INSPECTION SYSTEM PUSH-CABLE GUIDE APPARATUS; and U.S. Pat. No. 12,374,876, issued Jul. 29, 2025, entitled VIDEO INSPECTION SYSTEM APPARATUS AND METHODS WITH RELAY MODULES AND CONNECTION PORTS. The content of each of the above-described patents and applications is incorporated by reference herein in its entirety. The above applications may be collectively denoted herein as the “co-assigned applications” or “incorporated applications.”

The following exemplary embodiments are provided for the purpose of illustrating examples of various aspects, details, and functions of apparatus and systems; however, the described embodiments are not intended to be in any way limiting. It will be apparent to one of ordinary skill in the art that various aspects may be implemented in other embodiments within the spirit and scope of the present disclosure.

It is noted that as used herein, the term, “exemplary” means “serving as an example, instance, or illustration.” Any aspect, detail, function, implementation, and/or embodiment described herein as “exemplary” is not necessarily to be construed as preferred or advantageous over other aspects and/or embodiments.

### Terminology

As used herein, the term “complex bootable electronic device”, may refer to any tool, instrument, or other battery-powered device that, upon start up, may initially go through a “boot” procedure which is a process by which the device hardware is initialized and the operating system and firmware may be loaded to prepare the complex bootable electronic device for use. The boot procedure, which may be a lengthy process, may generally need to be initialized via the user (e.g., via pressing a button or the like). A “bootable” device, as used herein, may be any device that includes a boot procedure. Such devices may generally include a series of “operation setting” which may be settings or selections on the complex bootable electronic device configurable by the user (e.g., screen brightness, audio levels, wireless connections to other devices, and other settings which may be unique to the particular electronic device). As disclosed herein, a utility locator device is one example of a complex bootable electronic device.

The terms “dead” and “depleted” when referencing a battery or other power source may both refer to a battery or other power source lacking sufficient power remaining to power the host device.

The term “secondary power element” may be or include one or more batteries, supercapacitors, or other electrochemical double layer capacitors (EDLCs), or the like portable sources of electrical power.

The term “standby mode” may refer to a mode or state of the complex bootable electronic device in which some selective elements of the complex bootable electronic device may remain powered while other selective elements may not in order to preserve power. The elements selected to remain powered may, for instance, be selected based on the length of time it may take to reboot or return to a normal operating status. For instance, some elements selected to remain powered in the standby mode of a utility locator device or other complex bootable electronic device may be or include those responsible for GNSS tracking and geolocation fix, INS data including heading information, 1PPS (one pulse-per-second) and other phase locked circuits and elements, and the like.

### Example Battery Swapping Apparatus and Method Embodiments

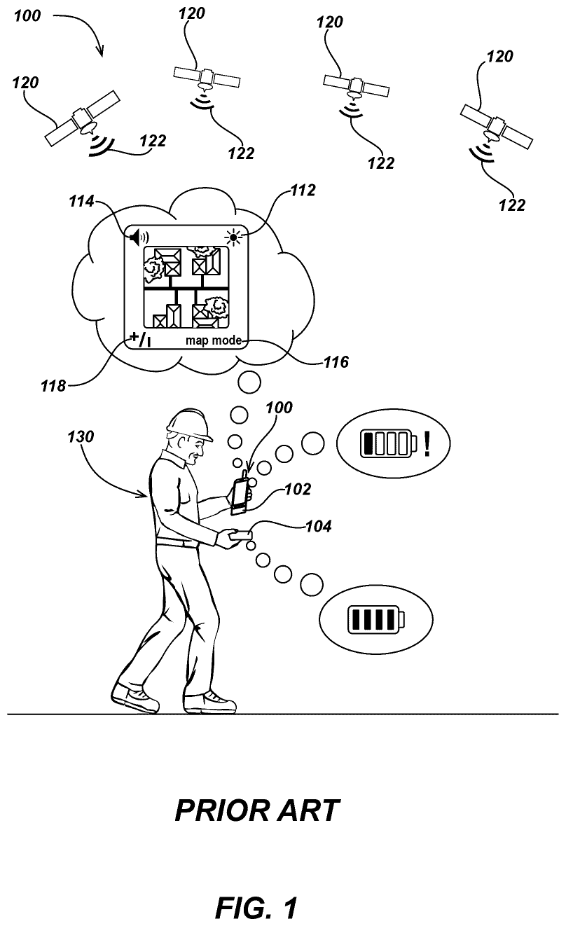

There are many situations where the unexpected or untimely depletion of a battery in a battery-powered device may be problematic. It may be particularly problematic in complex bootable electronic devices that may have a lengthy boot time once a battery has been replaced. For instance, in the prior art illustration of FIG. 1 a global navigation satellite system (GNSS) receiver 100 may require several minutes of boot or load time to acquire a fix on the signals 122 from a sufficient number of navigation satellites 120 in order to accurately determine positions upon replacing a dead or depleted battery 102 with a charged battery 104. Having a user wait for the GNSS receiver 100 and/or other complex bootable electronic device to reboot once the dead or depleted battery 102 has been replaced with the charged battery 104 may be incredibly inconvenient. Likewise, the fix of the GNSS receiver 100 may initially be of lesser quality (e.g., due to acquired signals 122 from fewer of the satellites 120) than the GNSS receiver 100 prior to dead or depleted battery 102 and as such may produce position solutions of lower quality on initial reboot.

Likewise, the GNSS receiver 100 may have various operation settings that must be reconfigured after experiencing a dead or depleted battery 102. For instance, the GNSS receiver 100 may include a user interface 110 having a brightness setting 112, control over audio levels 114, and choice of map mode 116 (e.g., topographic, aerial view maps, or the like), zoom level control 118, and the like. All such operation settings may need to be reconfigured by a user 130 each time the depleted battery 102 is replaced.

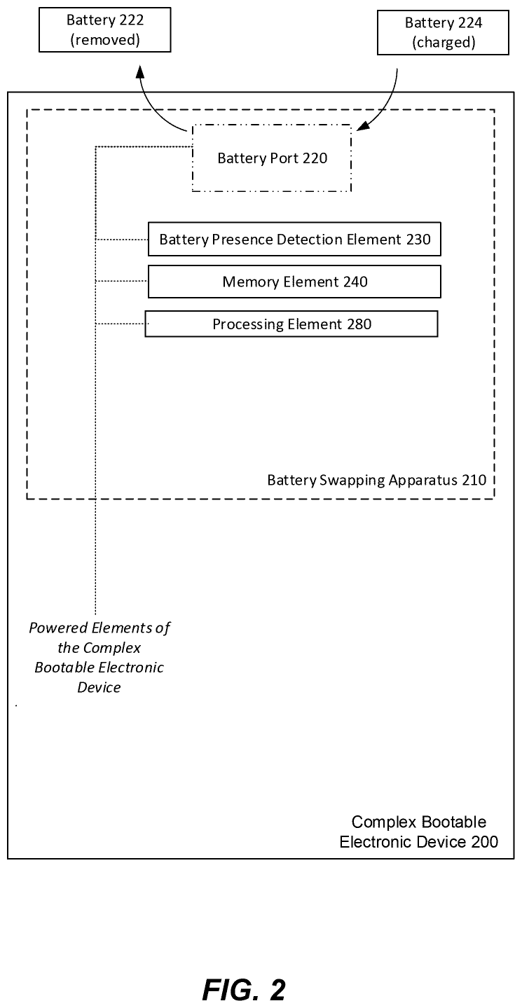

Turning to FIG. 2, a complex bootable electronic device 200 is illustrated that includes a battery swapping apparatus 210 in keeping with the present disclosure. The battery swapping apparatus 210 may include a battery port 220 for coupling a removeable battery 222 that may be replaced with a charged battery 224 as needed. As illustrated, the battery swapping apparatus 210 may further include a battery presence detection element 230 that is or includes a circuit or other element to detect the removal of the battery 220. Further, the battery swapping apparatus 210 may include a memory element 240 having one or more non-transitory memories to continually store the current operation settings of the complex bootable electronic device 210. Further, the complex bootable electronic device may include a processing element 280 to, upon reinstallation of a charged battery (e.g., the charged battery 224), reload the most recently stored operation settings of the complex bootable electronic device 200.

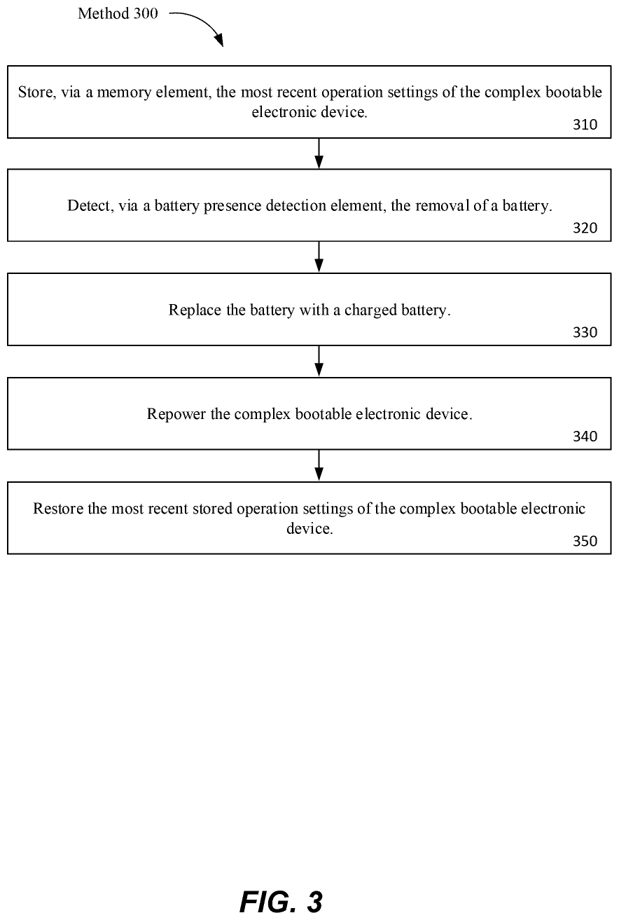

Turning To FIG. 3, a battery swapping method 300 for use with a battery swapping apparatus (e.g., the battery swapping apparatus 200 of FIG. 2 and/or other battery swapping apparatus of the present disclosure). The method 300 includes a step 310 storing, via a memory element, the most recent operation settings of the complex bootable electronic device. In a step 320, the method 300 includes detecting, via a battery presence detection element, the removal of a battery. In a step 330, the method 300 includes replacing the battery. Once a battery is replaced, the method 300 may proceed to a step 340 wherein the complex bootable electronic device may be repowered. It should be noted that the step 340 may include automatically repowering the complex bootable electronic device once the battery is replaced. In a step 350, the method 300 may include restoring the most recent stored operation settings of the complex bootable electronic device.

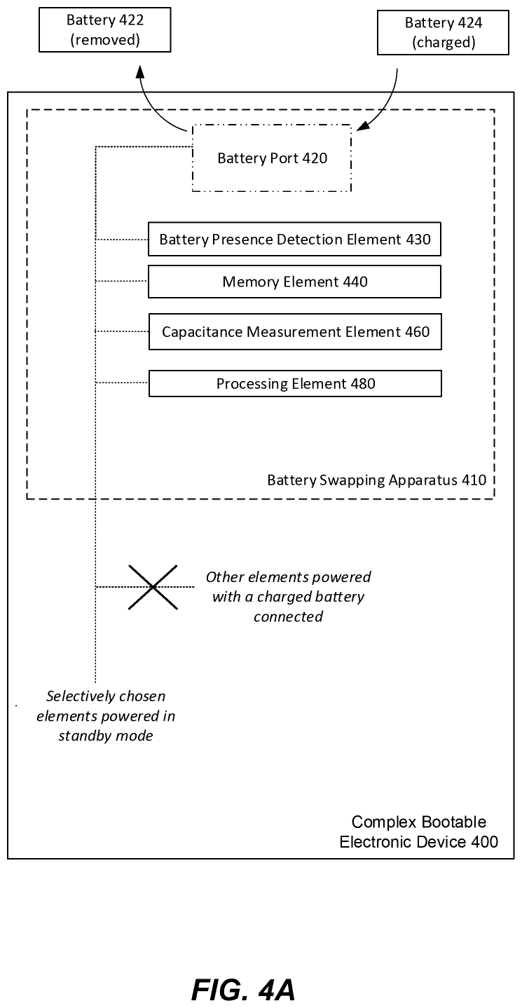

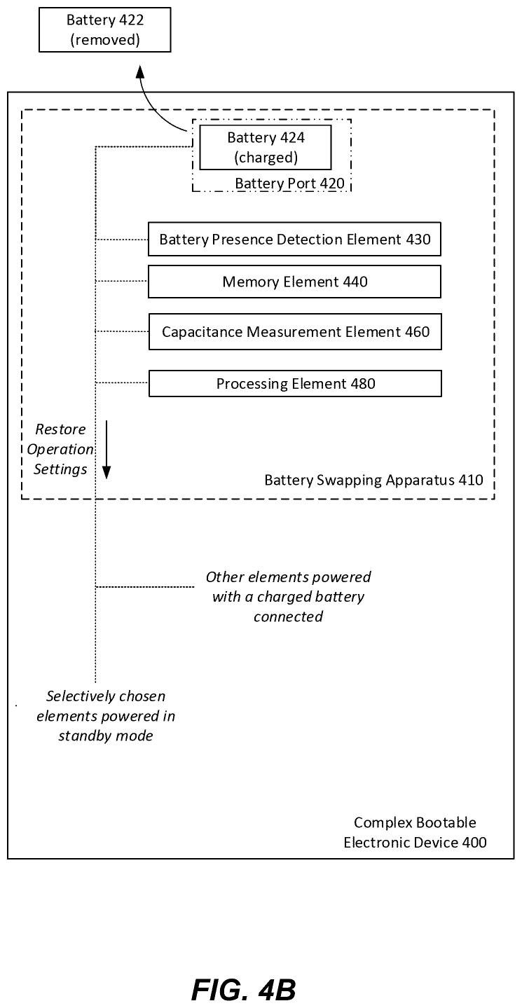

Turning to FIGS. 4A and 4B, a complex bootable electronic device 400 is illustrated that includes a battery swapping apparatus 410 in keeping with the present disclosure. The battery swapping apparatus 410 may include a battery port 420 for coupling a removeable battery 422 that may be replaced with a charged battery 424 as needed. As illustrated, the battery swapping apparatus 410 may further include a battery presence detection element 430 that is or includes a circuit or other element to detect the removal of the battery 420. Further, the battery swapping apparatus 410 may include a memory element 440 having one or more non-transitory memories to store the most recent operation settings of the complex bootable electronic device 410 prior to the removal of the battery 420. For instance, a memory image or the like containing the operational setting (e.g., most current device configurations and setting) may be dynamically stored in real-time or near real-time on flash memory or other memories of the memory element 440. The battery swapping apparatus 410 may further include a capacitance measurement element 460 including a circuit or other element to determine the remaining power capacity powering the complex bootable electronic device 400. For instance, the capacitance measurement element 460 may be or include a predetermined measure of time or a measurement that occurs at each instance a battery is removed expressed as a measure of power or estimated time that the complex bootable electronic device may maintain the standby mode. Further, the complex bootable electronic device may include a processing element 480 to switch the complex bootable electronic device 400 into the standby mode when the battery 410 is removed and restoring the most recent operation settings of the complex bootable electronic device 400 when a charged battery 422 is reinstalled prior to depletion of the remaining internal capacitance determined via the capacitance measurement element 460. For instance, the standby mode may include powering or choosing not to power selective elements of the specific complex bootable electronic device 400 to preserve the remaining power. For instance, wherein the complex bootable electronic device may be a utility locator device the standby mode may include powering elements responsible for GNSS tracking and geolocation fix, INS data including heading information, IPPS (one pulse-per-second) and other phase locked circuits and elements, and the like while shutting off power to graphic displays, lights, safety flashers, unnecessary processing, and the like. It should be noted that the most recent operation setting saved in the memory element 440 is retained during the standby mode so as to restore those operation setting upon restart the of the complex bootable electronic device 400 following restoring of full power upon exiting standby mode.

As shown in FIG. 4A, when a battery 422 is removed the complex bootable electronic device 400 may enter a standby mode. The standby mode may include selectively powering some elements of the complex bootable electronic device 400 while halting power to other elements. For instance, the standby mode may continue powering elements that have a long boot time and/or are necessary to the continuation of the task of the complex bootable electronic device 400. Likewise, elements selected to not be powered during standby mode may, for instance, include those that do not impact the boot time of the complex bootable electronic device 400 and/or are of minor importance to the continuation of the task of the complex bootable electronic device 400.

Further shown in FIG. 4B, when a charged battery 424 is reinstalled, the complex bootable electronic device 400 may exit standby mode. With the charged battery 424 reinstalled, the elements of the complex bootable electronic device 400 not powered during standby mode may once again be powered. Likewise, operation settings may be automatically restored upon restarting the complex bootable electronic device 400. It should be noted that restarting the complex bootable electronic device 400 may be automatically initiated upon replacing of the charged battery 424.

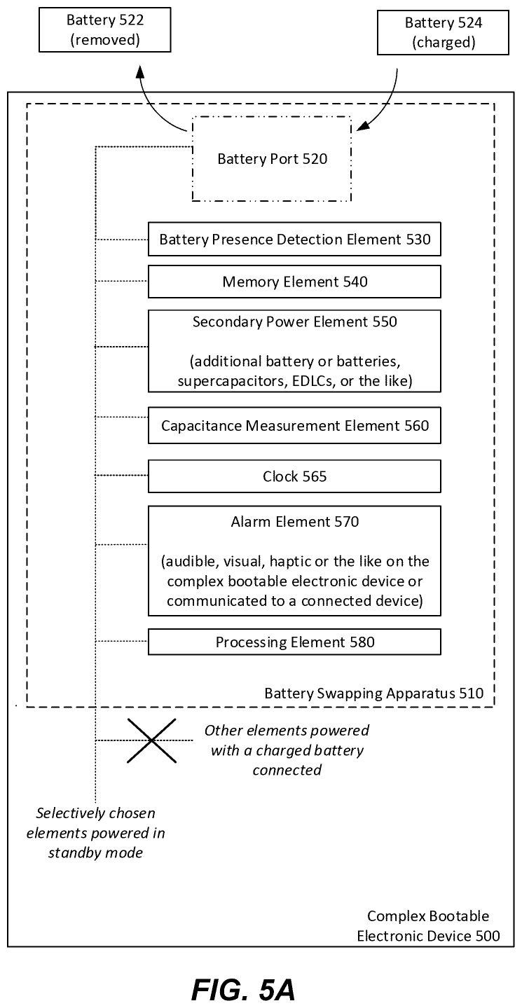

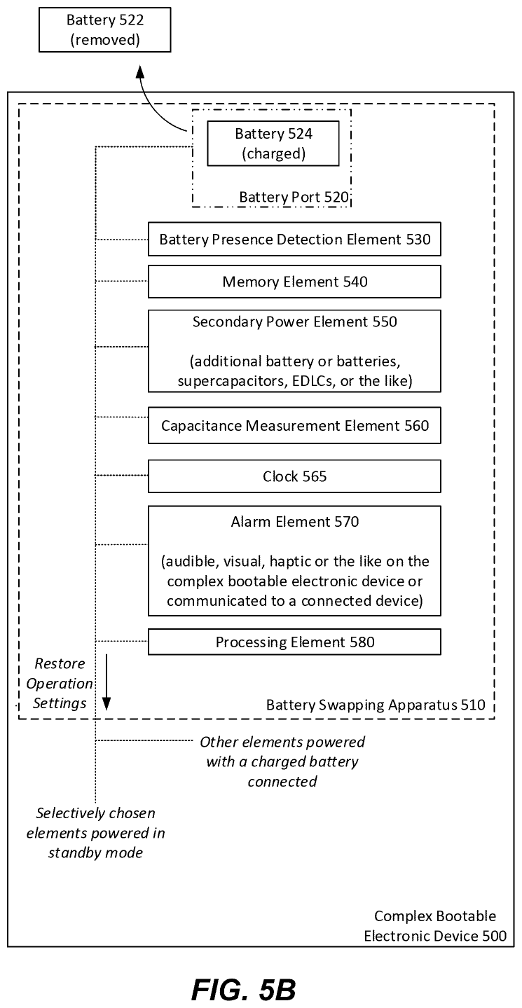

Turning to FIGS. 5A and 5B, another complex bootable electronic device 500 is illustrated that includes a battery swapping apparatus 510 in keeping with the present disclosure. The battery swapping apparatus 510 may include a battery port 520 for coupling a removeable battery 522 that may be replaced with a charged battery 524 as needed. The battery swapping apparatus 510 may further include a battery presence detection element 530 that is or includes a circuit or other element to detect the removal of the battery 520. Further, the battery swapping apparatus 510 may include a memory element 540 having one or more non-transitory memories to store the most recent operation settings of the complex bootable electronic device 510 prior to the removal of the battery 520. For instance, a memory image or the like containing the operational setting (e.g., most current device configurations and setting) may be dynamically stored in real-time or near real-time on flash memory or other memories of the memory element 540. The battery swapping apparatus 510 may optionally include a secondary power element 550 to provide electrical power to the complex bootable electronic device 500 when the primary battery is removed. The secondary power element 550 may, for instance, include one or more batteries, one or more supercapacitors or other electrochemical double layer capacitors (EDLCs), or the like to briefly power the complex bootable electronic device 500 or select elements of the complex bootable electronic device 500 to maintain in a standby mode. The battery swapping apparatus 510 may further include a capacitance measurement element 560 including a circuit or other element to determine the remaining power capacity powering the complex bootable electronic device 500. For instance, the capacitance measurement element 560 may be or include a predetermined measure of time or a measurement that occurs at each instance a battery is removed expressed as a measure of power or estimated time that the complex bootable electronic device may maintain the standby mode. In some embodiments, the capacitance measurement element 560 may optionally include a clock 565 to estimate a runtime until the remaining power capacity will be depleted. Optionally, an alarm element 570 may be included to alert a user of the imminent depletion of the remaining power capacity or a secondary power source (e.g., the secondary power element 550). Further, the complex bootable electronic device may include a processing element 580 to switch the complex bootable electronic device 500 into the standby mode when the battery 510 is removed and restoring the most recent operation settings of the complex bootable electronic device 500 when a charged battery 522 is reinstalled prior to depletion of the remaining internal capacitance determined via the capacitance measurement element 560. For instance, the standby mode may include powering or choosing not to power selective elements of the specific complex bootable electronic device 500 to preserve the remaining power. For instance, wherein the complex bootable electronic device may be a utility locator device the standby mode may include powering elements responsible for GNSS tracking and geolocation fix, INS data including heading information, 1PPS (one pulse-per-second) and other phase locked circuits and elements, and the like while shutting off power to graphic displays, lights, safety flashers, unnecessary processing, and the like. It should be noted that the most recent operation setting saved in the memory element 540 is retained during the standby mode so as to restore those operation setting upon restart the of the complex bootable electronic device 500 following restoring of full power upon exiting standby mode.

As shown in FIG. 5A, when a battery 522 is removed the complex bootable electronic device 500 may enter a standby mode. The standby mode may include selectively powering all or some select elements of the complex bootable electronic device 500 while halting power to other elements. For instance, the standby mode may continue powering elements that have a long boot time and/or are necessary to the continuation of the task of the complex bootable electronic device 500. Likewise, elements selected to not be powered during standby mode may, for instance, include those that do not impact the boot time of the complex bootable electronic device 500 and/or are of minor importance to the continuation of the task of the complex bootable electronic device 500.

Further shown in FIG. 5B, when a charged battery 524 is reinstalled, the complex bootable electronic device 500 may exit standby mode. With the charged battery 524 reinstalled, the elements of the complex bootable electronic device 500 not powered during standby mode may once again be powered. Likewise, operation settings may be automatically restored upon restarting the complex bootable electronic device 500. It should be noted that restarting the complex bootable electronic device 400 may be automatically initiated upon replacing of the charged battery 524.

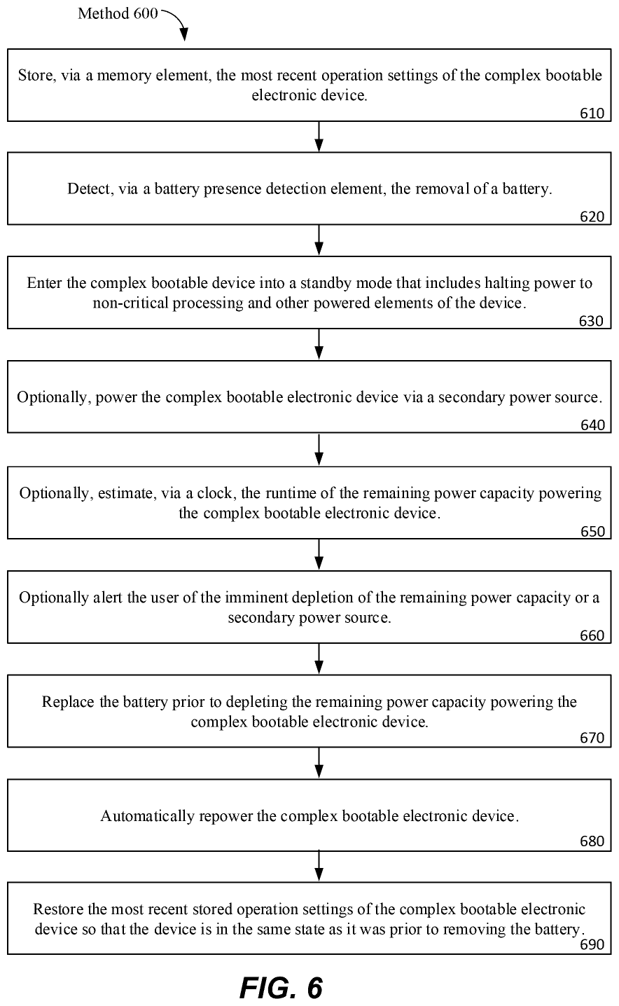

Turning to FIG. 6, the present disclosure relates to another battery swapping method 600 for use with a battery swapping apparatus (e.g., the battery swapping apparatus 210 of FIG. 2, the battery swapping apparatus 410 of FIGS. 4A and 4B, the battery swapping apparatus 510 of FIGS. 5A and 5B, and/or other battery swapping apparatus of the present disclosure). The method 600 may include a step 610 storing, via a memory element, the most recent operation settings of the complex bootable electronic device. In a step 620, the method 600 may include detecting, via a battery presence detection element, the removal of a battery. Further, the method 600 may include a step 630 entering the complex bootable device into a standby mode that includes halting power to non-critical processing and other powered elements of the device. In an optional step 640, the method 600 may include powering the complex bootable electronic device via a secondary power source (e.g., one or more batteries, supercapacitors or EDLCs, and the like) when the battery is removed. In another optional step 650, the method 600 may include estimating, via a clock, the runtime of the remaining power capacity powering the complex bootable electronic device. In another optional step 660, the method 600 may include alerting the user of the imminent depletion of the remaining power capacity or a secondary power source. Such an alert may be audible, visual, haptic or the like. For instance, the alert may include beeps or tones that become increasingly louder, more frequent, at a higher frequency or the like. Similarly, flashing lights or haptic feedback may be provided that gets increasingly more urgent it becomes to replace the depleted battery. In a step 670, the method 600 may further include replacing the battery prior to depleting the remaining power capacity powering the complex bootable electronic device. In a step 680, the complex bootable electronic device may be automatically repowered. The step 680 may include turning on or rebooting of elements that may have been powered off in the standby mode of the step 630. In a step 690, the method 600 may include restoring the most recently stored operation settings of the complex bootable electronic device so that the complex bootable electronic device is in the same state as it was prior to removing the battery.

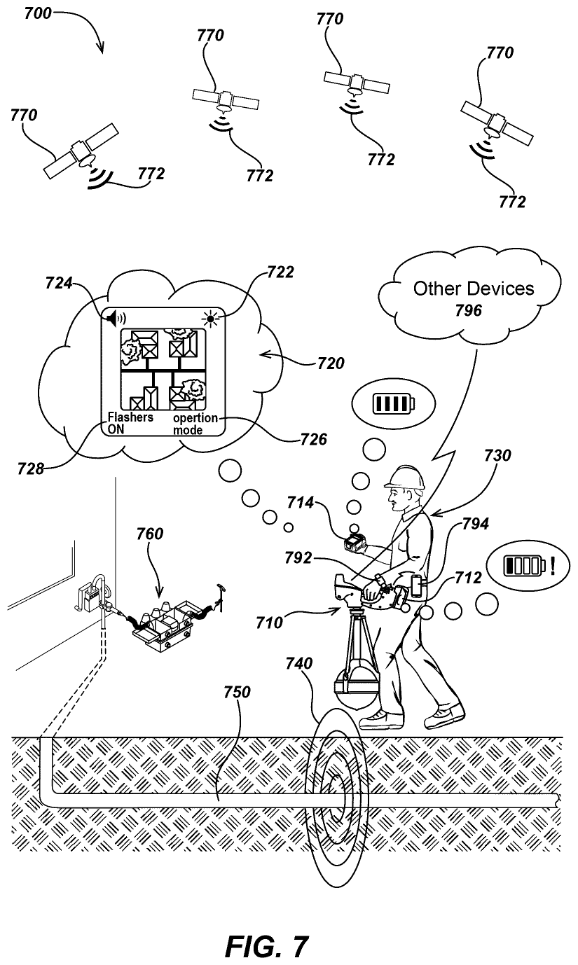

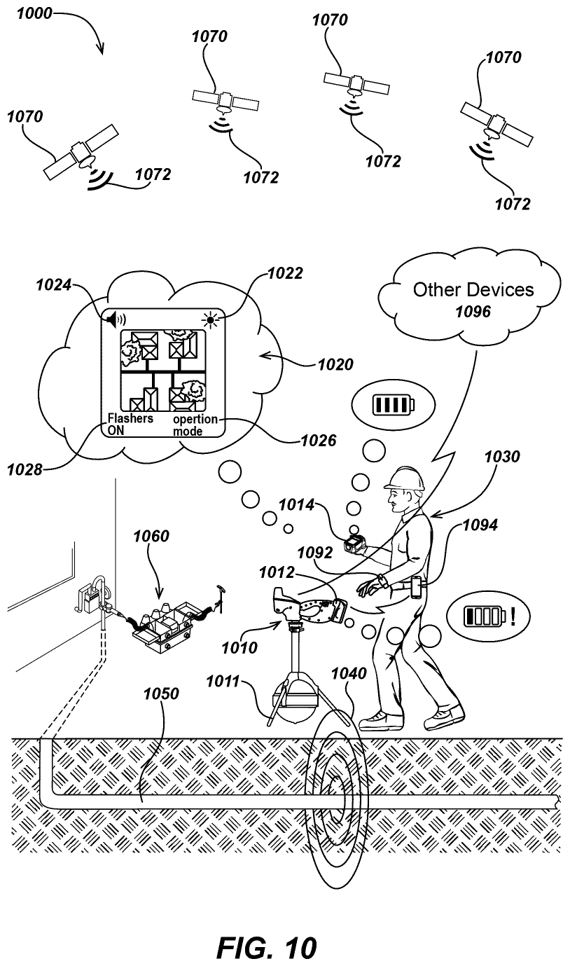

Utility locator devices are disclosed in the subsequent paragraphs as example complex bootable electronic devices that may employ a battery swapping apparatus and methods of the present invention. It should be noted, there are many other complex bootable electronic devices that benefit from a battery swapping apparatus and methods of the present invention. For instance, the complex bootable electronic devices of FIGS. 2-6 (e.g., the complex bootable electronic device 200 of FIG. 2, the complex bootable electronic device of the method 300 of FIG. 3, the complex bootable electronic device 400 of FIGS. 4A and 4B, the complex bootable electronic device 500 of FIGS. 5A and 5B, and the complex bootable electronic device of the method 600 of FIG. 6) may be or included in a signal transmitters (e.g., the transmitter device 760 of FIG. 7 or the transmitter device 1060 of FIG. 10) as well as inductive transmitters for coupling signals onto utility lines as well as other utility locating system devices of the incorporated patents and applications that include a battery swapping apparatus (e.g., the battery swapping apparatus 210 of FIG. 2, the battery swapping apparatus of the method 300 of FIG. 3, the battery swapping apparatus 410 of FIGS. 4A and 4B, the battery swapping apparatus 510 of FIGS. 5A and 5B, and the battery swapping apparatus of the method 600 of FIG. 6). Likewise, the complex bootable electronic devices of FIGS. 2-6 (e.g., the complex bootable electronic device 200 of FIG. 2, the complex bootable electronic device of the method 300 of FIG. 3, the complex bootable electronic device 400 of FIGS. 4A and 4B, the complex bootable electronic device 500 of FIGS. 5A and 5B, and the complex bootable electronic device of the method 600 of FIG. 6) may be or included in a camera control units, push-cable shooting devices, and other pipe inspection system devices of the incorporated patents and applications that include a battery swapping apparatus (e.g., the battery swapping apparatus 210 of FIG. 2, the battery swapping apparatus of the method 300 of FIG. 3, the battery swapping apparatus 410 of FIGS. 4A and 4B, the battery swapping apparatus 510 of FIGS. 5A and 5B, and the battery swapping apparatus of the method 600 of FIG. 6).

Turning to FIG. 7, a utility locating system 700 is illustrated that may include a utility locator device 710 that employs a battery swapping apparatus of the present disclosure. As illustrated, the utility locator device 710 may be carried by a user 730 about an area of interest to measure one or more electromagnetic signals 740 emitted by one or more utility lines, such as a utility line 750. The electromagnetic signals 740 may be coupled to the utility line 750 via a transmitter device 760, signals inherent in the utility line 750 (e.g., power or telecommunications lines), and/or from ambient signals present in the environment. The position of the utility line 750 may determine and, in combination with geospatial data, map the positions thereof. Such geospatial data may include position data in a world coordinate system such as that determine via a number of signals 772 broadcast from a plurality of navigation satellites 770 and received via one or more GNSS antennas and sensors in the utility locator device 710 as well as from inertial navigation sensors determining a pose, orientation, and direction at that position in the world coordinate system.

The utility locator device 710 may be or share aspects with those disclosed U.S. Pat. No. 7,332,901, issued Feb. 19, 2008, entitled LOCATOR WITH APPARENT DEPTH INDICATION; U.S. Pat. No. 8,264,226, issued Sep. 11, 2012, entitled SYSTEM AND METHOD FOR LOCATING BURIED PIPES AND CABLES WITH A MAN PORTABLE LOCATOR AND A TRANSMITTER IN A MESH NETWORK; U.S. Pat. No. 9,057,754, issued Jun. 16, 2015, entitled ECONOMICAL MAGNETIC LOCATOR APPARATUS AND METHOD; U.S. Pat. No. 9,435,907, issued Sep. 6, 2016, entitled PHASE SYNCHRONIZED BURIED OBJECT LOCATOR APPARATUS, SYSTEMS, AND METHODS; U.S. Pat. No. 9,927,546, issued Mar. 27, 2018, entitled PHASE-SYNCHRONIZED BURIED OBJECT TRANSMITTER AND LOCATOR METHODS AND APPARATUS; U.S. Pat. No. 10,162,074, issued Dec. 25, 2018, entitled UTILITY LOCATORS WITH RETRACTABLE SUPPORT STRUCTURES AND APPLICATIONS THEREOF; U.S. Pat. No. 10,670,766, issued Jun. 2, 2020, entitled UTILITY LOCATING SYSTEMS, DEVICES, AND METHODS USING RADIO BROADCAST SIGNALS; U.S. Pat. No. 10,690,795, issued Jun. 23, 2020, entitled LOCATING DEVICES, SYSTEMS, AND METHODS USING FREQUENCY SUITES FOR UTILITY DETECTION; and U.S. Pat. No. 10,809,408, issued Oct. 20, 2020, entitled DUAL SENSED LOCATING SYSTEMS AND METHODS; U.S. Pat. No. 11,196,181, issued Dec. 7, 2021, 2020, entitled LOW COST, HIGH PERFORMANCE SIGNAL PROCESSING IN A MAGNETIC-FIELD SENSING BURIED UTILITY LOCATOR SYSTEM; and/or others disclosed in the incorporated patents and applications. The content of each of these applications is incorporated by reference herein in its entirety.

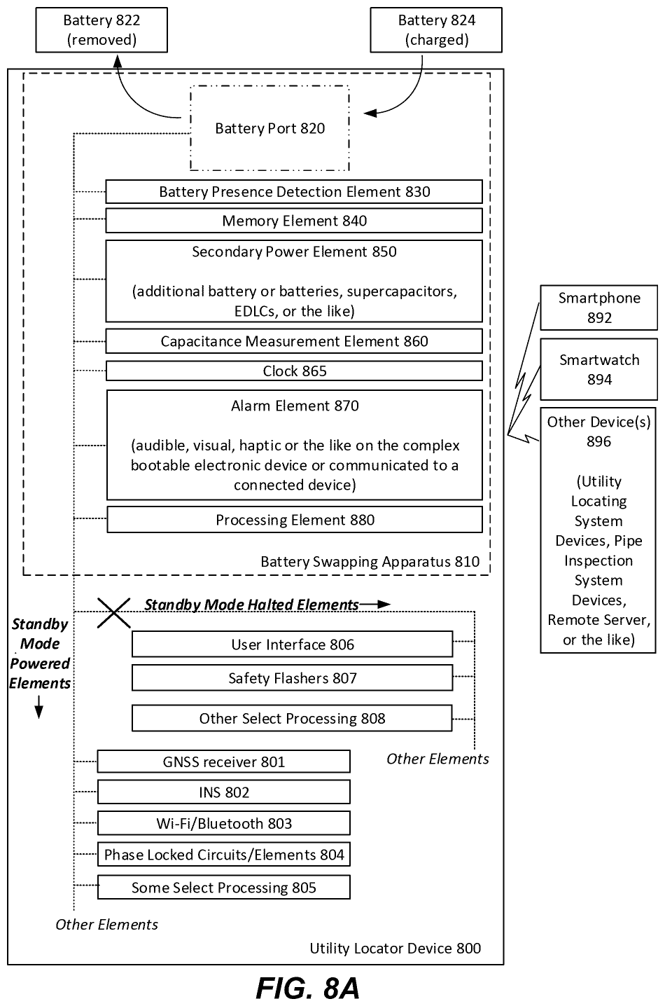

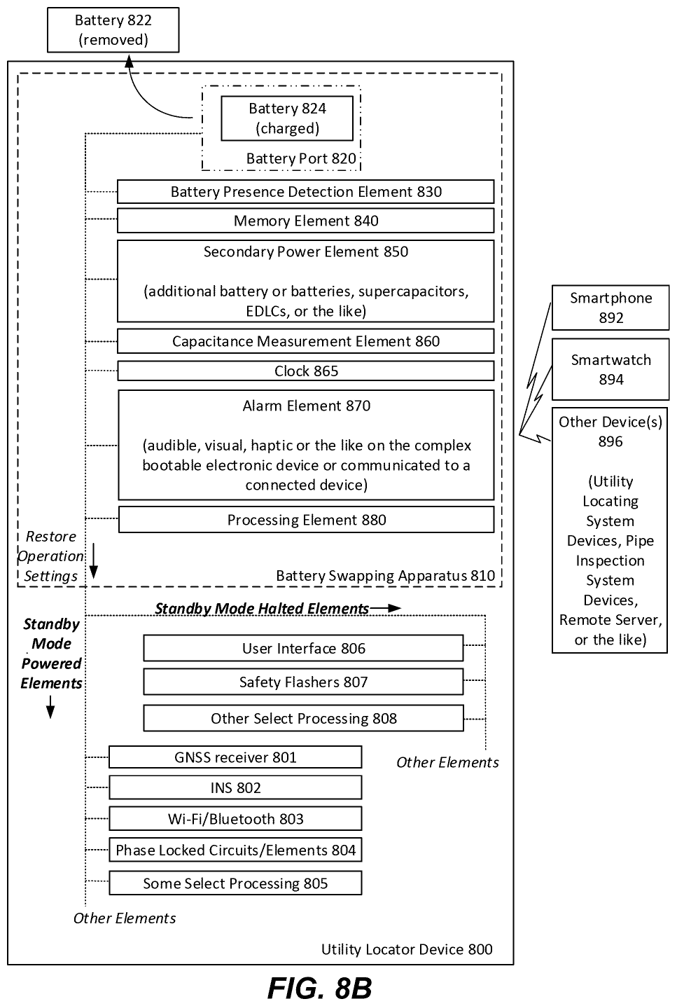

The utility locator device 710 may include a battery swapping apparatus (further shown with the utility locator device 800 diagramed in FIGS. 8A and 8B) such that when a battery 712 may need to be replaced (e.g., the battery has become depleted, is nearing depletion, or the like), the user may swap the battery 712 with a charged battery 714 and continue working with minimal disruption to the utility locating and mapping process. The battery swapping apparatus within the utility locator device 710 may allow the user 730 to avoid a lengthy boot process and further reconfiguring the operation settings of the utility locator device 710. For instance, the utility locator device 710 may include a user interface 720 having a brightness setting 722, control over audio levels 724, and choice of operation mode 726 (e.g., map vs locating mode), safety flashers control 728, and the like.

Further illustrated in FIG. 7, the utility locator device 710 may be in communication with one or more devices such as a smartwatch 792, smartphone 794, and other devices 796 (e.g., other system devices such as the transmitter device 760 and/or remote or cloud servers). Such devices may, in some embodiments, communicate alerts to the user 730 as to a low or depleted battery (e.g., the battery 712), the imminent depletion of a secondary power source or internal capacitance of the utility locator device 710, and/or communicate a runtime determined by a clock to estimate remaining time the utility locator device 710 may remain powered with the battery 712 removed.

Turning to FIGS. 8A and 8B, a utility locator device 800 is illustrated that includes a battery swapping apparatus 810 in keeping with the present disclosure. The utility locator device 800 may be or share aspects with the utility locator device 710 of FIG. 7 as well as other utility locator devices disclosed herein. The battery swapping apparatus 810 may include a battery port 820 for coupling a removeable battery 822 that may be replaced with a charged battery 824 as needed. The battery swapping apparatus 810 may further include a battery presence detection element 830 that is or includes a circuit or other element to detect the removal of the battery 820. Further, the battery swapping apparatus 810 may include a memory element 840 having one or more non-transitory memories to store the most recent operation settings of the complex bootable electronic device 810 prior to the removal of the battery 820. For instance, a memory image or the like containing the operational setting (e.g., most current device configurations and setting) of the utility locator device 800 may be dynamically stored in real-time or near real-time on flash memory or other memories of the memory element 840. The battery swapping apparatus 810 may optionally include a secondary power element 850 to provide electrical power to the utility locator device 800 when the battery is removed. The secondary power element 850 may, for instance, include one or more batteries, one or more supercapacitors or other electrochemical double layer capacitors (EDLCs), or the like to briefly power the utility locator device 800 or select elements of the utility locator device 800 to maintain in a standby mode. The battery swapping apparatus 810 may further include a capacitance measurement element 860 including a circuit or other element to determine the remaining power capacity powering the utility locator device 800. For instance, the capacitance measurement element 860 may be or include a predetermined measure of time or a measurement that occurs at each instance a battery is removed expressed as a measure of power or estimated time that the utility locator device 800 may maintain the standby mode. In some embodiments, the capacitance measurement element 560 may optionally include a clock 865 to estimate a runtime until the remaining power capacity will be depleted. Optionally, an alarm element 870 may be included to alert a user of the imminent depletion of the remaining power capacity or a secondary power source (e.g., the secondary power element 850). Further, the complex bootable electronic device may include a processing element 880 to switch the utility locator device 800 into the standby mode when the battery 810 is removed and restoring the most recent stored operation settings of the utility locator device 800 when a charged battery 822 is reinstalled prior to depletion of the remaining internal capacitance determined via the capacitance measurement element 860. For instance, the standby mode may include powering or choosing not to power selective elements of the specific utility locator device 800 to preserve the remaining power. For instance, the standby mode may include powering elements responsible for GNSS tracking and geolocation fix, INS data including heading information, 1PPS (one pulse-per-second) and other phase locked circuits and elements, and the like while shutting off power to graphic displays, lights, safety flashers, unnecessary processing, and the like. It should be noted that the most recent operation setting saved in the memory element 840 is retained during the standby mode so as to restore those operation setting upon restart the of the utility locator device 800 following restoring of full power upon exiting standby mode.

As shown in FIG. 8A, when a battery 822 is removed the utility locator device 800 may enter a standby mode. The standby mode may include selectively powering all or some select elements of the utility locator device 800 while halting power to other elements. For instance, the standby mode may continue powering elements that have a long boot time and/or are necessary to the continuation of the task of the utility locator device 800 (e.g., GNSS receivers 801, inertial navigation sensors [INS] 802, Wi-Fi/Bluetooth 803 or other communication elements, phase locked circuits and elements 804 (e.g., those related to GNSS signals, electromagnetic signals from the utility line or lines, and like phase locked signals), and some select processing 805). Likewise, elements selected to not be powered during standby mode may, for instance, include those that do not impact the boot time of the utility locator device 800 and/or are of minor importance to the continuation of the task of the utility locator device 800 (e.g., user interface 806, safety flashers 807, and other select processing 808).

Further shown in FIG. 8B, when the charged battery 824 is reinstalled, the utility locator device 800 may exit standby mode. With the charged battery 824 reinstalled, the elements of the complex bootable electronic device 800 not powered during standby mode may once again be powered. Likewise, operation settings of the utility locator device 800 may be automatically restored upon installing the charged battery 824 allowing a user to continue with the utility locating and mapping procedure with minimal disruption.

Further illustrated in FIGS. 8A and 8B, the utility locator device 800 may be in communication with one or more devices such as a smartwatch 892, smartphone 894, and other devices 896 (e.g., other utility locating or pipe inspection system devices and/or remote or cloud servers). Such devices may, in some embodiments, communicate alerts to the user as to a low or depleted battery or the imminent depletion of a secondary power source or internal capacitance of the utility locator device 800 (e.g., via the alarm element 870) and/or communicate a runtime determined by a clock (e.g., the clock 865) to estimate remaining time the utility locator device 800 may remain powered with the battery 822 removed.

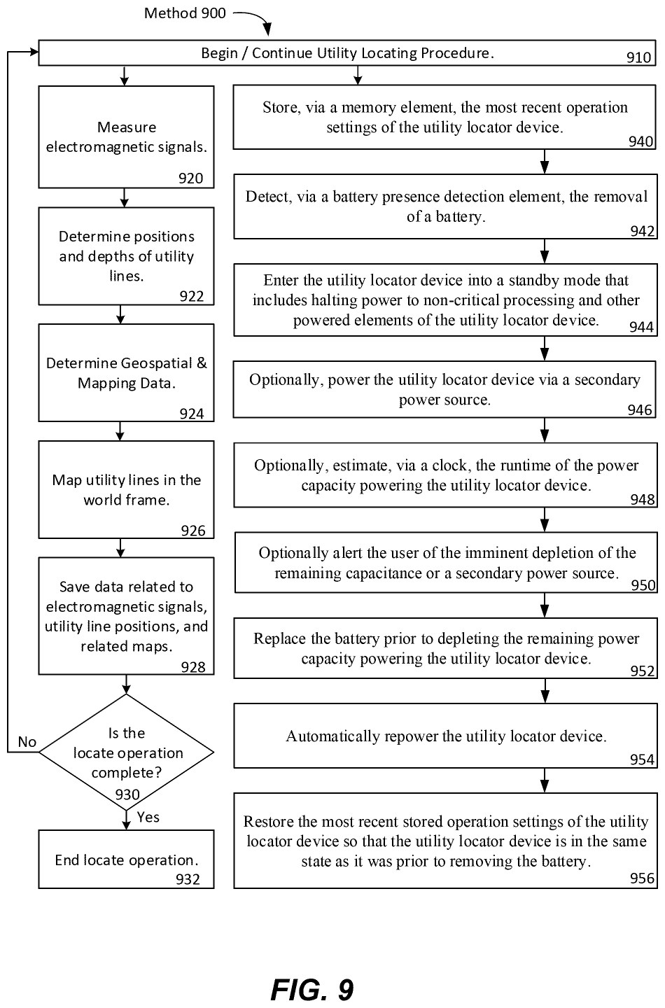

Turning to FIG. 9, a method 900 is disclosed for locating and mapping utility lines with devices having a battery swapping apparatus of the present disclosure. In a step 910, the utility locating procedure may begin (or optionally continue in further iterations of running the same method). The method 900 may, after the step 910, continue into two separate series of steps. For instance, the steps 920-932 may disclose the process of locating and mapping utility lines whereas the steps 940-954 may disclose the operation of a battery swapping apparatus as deployed in the utility locating system device.

Continuing with the steps 920-932 for locating and mapping utility lines, a step 920 may include measuring electromagnetic signals via a utility locator device (e.g., the utility locator device 710 of FIG. 7, the utility locator device 800 of FIGS. 8A and 8B, the utility locator device 1010 of FIG. 10, and/or other utility locator devices of the incorporated patents and applications). Such electromagnetic signals may be passive and/or coupled to one or more utility lines via a transmitter device (e.g., the transmitter device 760 of FIG. 7 and/or other transmitter devices of the incorporated patents and applications). In a step 924, the method 900 may include determining utility line positions and depths. The step 924 may include or share aspects with the methods for determining utility line positions and depths disclosed in U.S. Pat. No. 7,332,901, issued Feb. 19, 2008, entitled LOCATOR WITH APPARENT DEPTH INDICATION; U.S. Pat. No. 8,264,226, issued Sep. 11, 2012, entitled SYSTEM AND METHOD FOR LOCATING BURIED PIPES AND CABLES WITH A MAN PORTABLE LOCATOR AND A TRANSMITTER IN A MESH NETWORK; U.S. Pat. No. 9,057,754, issued Jun. 16, 2015, entitled ECONOMICAL MAGNETIC LOCATOR APPARATUS AND METHOD; U.S. Pat. No. 9,435,907, issued Sep. 6, 2016, entitled PHASE SYNCHRONIZED BURIED OBJECT LOCATOR APPARATUS, SYSTEMS, AND METHODS; U.S. Pat. No. 9,927,546, issued Mar. 27, 2018, entitled PHASE-SYNCHRONIZED BURIED OBJECT TRANSMITTER AND LOCATOR METHODS AND APPARATUS; U.S. Pat. No. 10,162,074, issued Dec. 25, 2018, entitled UTILITY LOCATORS WITH RETRACTABLE SUPPORT STRUCTURES AND APPLICATIONS THEREOF; U.S. Pat. No. 10,670,766, issued Jun. 2, 2020, entitled UTILITY LOCATING SYSTEMS, DEVICES, AND METHODS USING RADIO BROADCAST SIGNALS; U.S. Pat. No. 10,690,795, issued Jun. 23, 2020, entitled LOCATING DEVICES, SYSTEMS, AND METHODS USING FREQUENCY SUITES FOR UTILITY DETECTION; and U.S. Pat. No. 10,809,408, issued Oct. 20, 2020, entitled DUAL SENSED LOCATING SYSTEMS AND METHODS; U.S. Pat. No. 11,196,181, issued Dec. 7, 2021, 2020, entitled LOW COST, HIGH PERFORMANCE SIGNAL PROCESSING IN A MAGNETIC-FIELD SENSING BURIED UTILITY LOCATOR SYSTEM; and/or others disclosed in the incorporated patents and applications. The content of each of these applications is incorporated by reference herein in its entirety.

In a step 924, the method 900 may include determining geospatial and mapping data. For instance, such geospatial and mapping data may include one or more GNSS receivers and antennas (e.g., GPS, GLONASS, Bei Dou, Galileo, and the like) for determining a position in the world frame and one or more inertial navigation system sensors to determine an orientation/pose at each position. Likewise, such geospatial and mapping data may include maps of the locate environment as well as asset tagging information. In a step 926, the method 900 may include mapping utility lines in the world frame. In a step 928, the method 900 may include saving data relating to electromagnetic signals, utility line positions, and related maps in a memory element having one or more non-transitory memories. In a decision step 930, it may be decided whether the locating operation is ended. For instance, it should be determined whether the locate environment has been sufficiently covered or not. If the locate operation is not complete, the method 900 may repeat back at the step 910. Optionally, the utility locator device may be moved in space and/or time for the next iteration of the method 900. If, back in the decision step 930, that the locate environment has been sufficiently covered the method may continue onto a step 932 wherein the locate operation may end.

Continuing back with the steps 940-954 relating to the operation of a battery swapping apparatus, which may run simultaneously or near simultaneously with the steps 920-932 for locating and mapping utility lines. A step 940 may include storing, via a memory element, the most recent operation settings of the utility locator device. In a step 942, the method 900 may include detecting, via a battery presence detection element, the removal of a battery. Further, the method 900 may include a step 944 entering the utility locator device into a standby mode that includes halting power to non-critical processing and other powered elements of the device. In an optional step 946, the method 900 may include powering the utility locator device via a secondary power source (e.g., one or more batteries, supercapacitors or EDLCs, and the like) when the battery is removed. In another optional step 948, the method 900 may include estimating, via a clock, the runtime of the remaining power capacity powering the utility locator device. In another optional step 950, the method 900 may include alerting the user of the imminent depletion of the remaining power capacity or a secondary power source. In a step 952, the method 900 may further include replacing the battery prior to depleting the remaining power capacity powering the utility locator device. In a step 954, the method 900 may include restoring the most recently stored operation settings of the utility locator device. In a step 954, the complex bootable electronic device may be automatically repowered. The step 954 may include turning on or rebooting of elements that may have been powered off in the standby mode of the step 944. In a step 956, the method 900 may include restoring the most recently stored operation settings of the utility locator device so that the utility locator device is in the same state as it was prior to removing the battery.

Turning to FIG. 10, another utility locating system 1000 is illustrated that may include a utility locator device 1010 that employs a battery swapping apparatus of the present disclosure. As illustrated, the utility locator device 1010 may be self-supported via a tripod mechanism 1011 while measuring one or more electromagnetic signals 1040 emitted by one or more utility lines, such as a utility line 1050. The tripod mechanism 1011 may free the hands of a user 1030 to swap batteries such as swapping out a depleted battery 1012 for a charged battery 1014. The tripod mechanism 1011 may be or share aspects with the support structures disclosed U.S. Pat. No. 10,162,074, issued Dec. 25, 2018, entitled UTILITY LOCATORS WITH RETRACTABLE SUPPORT STRUCTURES AND APPLICATIONS THEREOF and/or others disclosed in the incorporated patents and applications. The content of each of these applications is incorporated by reference herein in its entirety.

The electromagnetic signals 1040 may be coupled to the utility line 1050 via a transmitter device 1060, signals inherent in the utility line 1050 (e.g., power or telecommunications lines), and/or from ambient signals present in the environment. The position of the utility line 1050 may determine and, in combination with geospatial data, map the positions thereof. Such geospatial data may include position data in a world coordinate system such as that determine via a number of signals 1072 broadcast from a plurality of navigation satellites 1070 and received via one or more GNSS antennas and sensors in the utility locator device 1010 as well as from inertial navigation sensors determining a pose, orientation, and direction at that position in the world coordinate system.

The utility locator device 1010 may be or share aspects with those disclosed U.S. Pat. No. 7,332,901, issued Feb. 19, 2008, entitled LOCATOR WITH APPARENT DEPTH INDICATION; U.S. Pat. No. 8,264,226, issued Sep. 11, 2012, entitled SYSTEM AND METHOD FOR LOCATING BURIED PIPES AND CABLES WITH A MAN PORTABLE LOCATOR AND A TRANSMITTER IN A MESH NETWORK; U.S. Pat. No. 9,057,754, issued Jun. 16, 2015, entitled ECONOMICAL MAGNETIC LOCATOR APPARATUS AND METHOD; U.S. Pat. No. 9,435,907, issued Sep. 6, 2016, entitled PHASE SYNCHRONIZED BURIED OBJECT LOCATOR APPARATUS, SYSTEMS, AND METHODS; U.S. Pat. No. 9,927,546, issued Mar. 27, 2018, entitled PHASE-SYNCHRONIZED BURIED OBJECT TRANSMITTER AND LOCATOR METHODS AND APPARATUS; U.S. Pat. No. 10,162,074, issued Dec. 25, 2018, entitled UTILITY LOCATORS WITH RETRACTABLE SUPPORT STRUCTURES AND APPLICATIONS THEREOF; U.S. Pat. No. 10,670,766, issued Jun. 2, 2020, entitled UTILITY LOCATING SYSTEMS, DEVICES, AND METHODS USING RADIO BROADCAST SIGNALS; U.S. Pat. No. 10,690,795, issued Jun. 23, 2020, entitled LOCATING DEVICES, SYSTEMS, AND METHODS USING FREQUENCY SUITES FOR UTILITY DETECTION; and U.S. Pat. No. 10,809,408, issued Oct. 20, 2020, entitled DUAL SENSED LOCATING SYSTEMS AND METHODS; U.S. Pat. No. 11,196,181, issued Dec. 7, 2021, 2020, entitled LOW COST, HIGH PERFORMANCE SIGNAL PROCESSING IN A MAGNETIC-FIELD SENSING BURIED UTILITY LOCATOR SYSTEM; and/or others disclosed in the incorporated patents and applications. The content of each of these applications is incorporated by reference herein in its entirety.

The utility locator device 1010 may include a battery swapping apparatus which may be or share aspects with the battery swapping apparatus 810 the utility locator device 800 disclosed in FIGS. 8A and 8B or other battery swapping apparatus disclosed herein. The battery swapping apparatus may facilitate swapping of the battery 1012 (e.g., the battery has become depleted, is nearing depletion, or the like) with a charged battery 1014 and continue working with minimal disruption to the utility locating and mapping process. The battery swapping apparatus within the utility locator device 1010 may allow the user 1030 to avoid a lengthy boot process and further reconfiguring the operation settings of the utility locator device 1010. For instance, the utility locator device 1010 may include a user interface 1020 having a brightness setting 1022, control over audio levels 1024, and choice of operation mode 1026 (e.g., map vs locating mode), safety flashers control 1028, and the like.

Further illustrated in FIG. 10, the utility locator device 1010 may be in communication with one or more devices such as a smartwatch 1092, smartphone 1094, and other devices 1096 (e.g., other system devices such as the transmitter device 1060 and/or remote or cloud servers). Such devices may, in some embodiments, communicate alerts to the user 1030 as to a low or depleted battery (e.g., the battery 1012), the imminent depletion of a secondary power source or internal capacitance of the utility locator device 1010, and/or communicate a runtime determined by a clock to estimate remaining time the utility locator device 1010 may remain powered with the battery 1012 removed.

Those of skill in the art would understand that information and signals, such as video and/or audio signals or data, control signals, or other signals or data may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the embodiments disclosed herein may be implemented as electronic hardware, computer software, electro-mechanical components, or combinations thereof. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative functions and circuits described in connection with the embodiments disclosed herein with respect to tools, instruments, and other described devices may be implemented or performed in one or more processing elements using elements such as a general or special purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Processing elements may include hardware and/or software/firmware to implement the functions described herein in various combinations. Processing elements, as used herein, may also include networked computers or computing systems, cloud-based computing, machine learning, and Artificial Intelligence (AI) systems. It is foreseeable that other processing systems, methods, and devices not listed here could be used by one of ordinary skill in the art to accomplish processing, computing, and memory tasks and functions.

The previous description of the disclosed embodiments is provided to enable any person skilled in the art to make or use various embodiments. Various modifications to these embodiments will be readily apparent to those skilled in the art, and the generic principles defined herein may be applied to other embodiments without departing from the spirit or scope of the disclosure.

Accordingly, the presently claimed invention is not intended to be limited to the aspects shown herein, but is to be accorded the full scope consistent with the specification and drawings, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c.

The previous description of the disclosed aspects is provided to enable any person skilled in the art to make or use the present disclosure. Various modifications to these aspects will be readily apparent to those skilled in the art, and the generic principles defined herein may be applied to other aspects without departing from the spirit or scope of the disclosure. Thus, the scope of the present disclosure is not intended to be limited to the aspects shown herein but is to be accorded the widest scope consistent with the appended claims and their equivalents.

We claim:

1. A battery swapping apparatus for use in complex bootable electronic devices, comprising:
a removeable battery;
a battery presence detection element to detect the removal of the battery;
a memory element having one or more non-transitory memories to continually store the most current operation settings of the complex bootable electronic device prior to the removal of the battery; and
a processing element to, upon reinstallation of a charged battery, reload the most recently stored operation settings of the complex bootable electronic device.

2. The battery swapping apparatus of claim 1, employed in a utility locator device having one or more antennas and associated receiver circuitry to determine positions of and map buried utility lines.

3. A battery swapping apparatus for use in complex bootable electronic devices, comprising:
a removeable battery;
a battery presence detection element to detect the removal of the battery;
a memory element having one or more non-transitory memories to continually store the operation settings of the complex bootable electronic device prior to the removal of the battery;
a capacitance measurement element to determine the remaining power capacity powering the complex bootable electronic device in a standby mode that includes selectively halting power to the non-critical processing and other elements; and
a processing element to switch the complex bootable electronic device into the standby mode when the battery is removed and restoring the most recent stored operation settings of the complex bootable electronic device when a charged battery is reinstalled prior to depletion of the remaining internal capacitance determined via the capacitance measurement element.

4. The battery swapping apparatus of claim 3, wherein the capacitance measurement element includes a predetermined measure of time that the complex bootable electronic device may maintain the standby mode.

5. The battery swapping apparatus of claim 3, wherein the capacitance measurement element includes a clock to estimate a runtime until the remaining power capacity is depleted.

6. The battery swapping apparatus of claim 3, further including a secondary power element to provide electrical power to the complex bootable electronic device when the primary battery is removed.

7. The battery swapping apparatus of claim 6, wherein the secondary power element includes one or more supercapacitors or other electrochemical double layer capacitors (EDLCs).

8. The battery swapping apparatus of claim 6, wherein the secondary power element includes one or more batteries.

9. The battery swapping apparatus of claim 3, further including an alert element to communicate an alert to a user of the imminent depletion of the measured remaining power capacity or a secondary power source.

10. The battery swapping apparatus of claim 3, employed in a utility locator device having one or more antennas and associated receiver circuitry to determine positions of and map buried utility lines.

11. A battery swapping method for use with a battery swapping apparatus, comprising:
storing, via a memory element, the operation settings of the complex bootable electronic device prior to the removal of the battery;
detecting, via a battery presence detection element, the removal of a battery;
replacing the battery; and
restoring the most recent stored operation settings of the complex bootable electronic device.

12. The method of claim 11, used in a combined utility locating method to determine the positions of and map utility lines.

13. A battery swapping method for use with a battery swapping apparatus, comprising:
storing, via a memory element, the operation settings of the complex bootable electronic device prior to the removal of the battery;
detecting, via a battery presence detection element, the removal of a battery;
entering a standby mode that includes halting power to non-critical processing and other powered elements of the complex bootable electronic device;
measuring, via a capacitance measurement element, the remaining power capacity powering the complex bootable electronic device;
replacing the battery prior to depleting the remaining power capacity powering the complex bootable electronic device;
automatically restarting the complex bootable electronic device; and
restoring the most recent operation settings of the complex bootable electronic device prior to the removal of the battery.

14. The method of claim 13, further including powering the complex bootable electronic device via a secondary power source when the battery is removed.

15. The method of claim 13, further including estimating, via a clock, the runtime of the remaining power capacity powering the complex bootable electronic device as measured via the capacitance measurement element.

16. The method of claim 13, used in a combined utility locating method to determine the positions of and map utility lines.

17. The method of claim 13, further including one or more steps to alert the user of the imminent depletion of the remaining power capacity or a secondary power source.
